(19) United States
(12) Patent Application Publication
(10) Pub. No.: US 2024/0341067 A1
(43) Pub. Date: Oct. 10, 2024

(54) Modular Cooling Systems and Methods

(71) Applicant: Hoffman Enclosures Inc., Anoka, MN (US)

(72) Inventors: William Martin, Brooklyn Center, MN (US); Matthew Archibald, Derry, NH (US)

(21) Appl. No.: 18/629,837

(22) Filed: Apr. 8, 2024

Related U.S. Application Data
(60) Provisional application No. 63/495,001, filed on Apr. 7, 2023.

(51) Int. Cl. H05K 7/20

(52) U.S. Cl. CPC H05K 7/20836; H05K 7/20327; H05K 7/20354; H05K 7/20818

(57) ABSTRACT

Modular liquid cooling system and method for a data center. The system includes a first cooling unit with a liquid-to-liquid heat exchanger and a first valve and a second cooling unit and a second valve. When the first valve is open, the liquid-to-liquid heat exchanger is positioned fluidly along a first flow path. When the approach temperature differential is less than zero, a controller closes the first valve to the first cooling unit. When an approach temperature differential is less a predetermined approach temperature differential, the controller opens the second valve to the second cooling unit.

### CROSS-REFERENCE TO RELATED APPLICATIONS

This application claims priority to U.S. Provisional Patent Application No. 63/495,001 filed Apr. 7, 2023, the entirety of which is incorporated by reference.

### BACKGROUND

Cooling systems can be provided for electrical components in data centers. In some cases, data centers include liquid cooling circuits, which provide liquid coolant to electronics housed within the data center. The liquid coolant can be pumped through the liquid cooling circuit by pumps to provide a continuous cooling of electronic components of the data center.

### SUMMARY

Embodiments of the disclosure provide a method of cooling electrical equipment within a data center. The method includes determining an approach temperature differential between a first fluid between a primary inlet and a primary outlet and a second fluid between a secondary inlet and a secondary outlet. When the approach temperature differential is greater than zero, the system provides the first fluid and the second fluid to a first liquid-to-liquid heat exchanger to transfer heat from the second fluid to the first fluid. When the approach temperature differential is less than a predetermined approach temperature differential, the system provides the first fluid and the second fluid to a first chilling unit including a refrigerant, an evaporator, and a condenser. The system transfers heat from the second fluid to the refrigerant at the evaporator and from the refrigerant to the first fluid at the condenser.

Some embodiments of the disclosure provide a modular liquid cooling system for a data center. The modular liquid cooling system includes a primary inlet and a primary outlet defining a first flow path for a first fluid, and a secondary inlet and a secondary outlet defining a second flow path for a second fluid. The system includes a first cooling unit with a first liquid-to-liquid heat exchanger having a predetermined approach temperature differential, and a first valve defining a first open position and a first closed position. The system includes a second cooling unit including a second valve defining a second open position and a second closed position. The system further includes a controller in communication with the first valve and the second valve. The controller determines an approach temperature differential between the first fluid along the first flow path and the second fluid along the second flow path. When the approach temperature differential is less than zero, the controller provides a first signal to the first valve to move the first valve to the closed position. When the approach temperature differential is less than the predetermined approach temperature differential, the controller provides a second signal to the second valve to move the second valve to the second open position.

### BRIEF DESCRIPTION OF THE DRAWINGS

FIG. 1 is a schematic illustration of an example cooling system for electrical equipment of a data center;

FIG. 2 is a schematic illustration of a liquid-to-liquid (LTL) coolant distribution unit (CDU) for use within a data center, according to some aspects of the disclosure;

FIG. 3 is a graph illustrating a minimum approach temperature differential (ATD) for a LTL heat exchanger of a LTL CDU, according to some aspects;

FIG. 4 is a schematic illustration of a modular CDU, according to some aspects of the disclosure;

FIG. 5 is a graph illustrating a relationship between a fluid temperature of a facility water supply (FWS) and a fluid temperature of a technology cooling system (TCS) according to some aspects of the disclosure;

FIG. 6 is a schematic illustration of an example CDU including a plurality of chilling modules, according to some aspects of the disclosure;

FIG. 7 is a schematic illustration of a chilling module for use in the CDU of FIG. 6;

FIG. 8 is a schematic illustration of a modular cooling system for a data center, according to some aspects of the disclosure;

FIG. 9 is a schematic illustration of a modular cooling system for a data center, according to some aspects of the disclosure;

FIG. 10 is a schematic illustration of a modular cooling system for a data center, according to some aspects of the disclosure;

FIG. 11 is a schematic illustration of a modular cooling system for a data center, according to some aspects of the disclosure;

FIG. 12 is a schematic illustration of a modular cooling system for a data center, according to some aspects of the disclosure;

FIG. 13 is a schematic illustration of a control system for a CDU according to some aspects of the disclosure;

FIG. 14 is a schematic illustration of a control system for a modular cooling system, according to some aspects of the disclosure; and

FIG. 15 is a flowchart illustrating a process for operating a modular cooling system.

### DETAILED DESCRIPTION

Before any embodiments of the present disclosure are explained in detail, it is to be understood that the present disclosure is not limited in its application to the details of construction and the arrangement of components set forth in the following description or illustrated in the following drawings. The disclosed systems and methods are capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

Similarly, unless otherwise limited or defined, “or” indicates a non-exclusive list of components or operations that can be present in any variety of combinations, rather than an exclusive list of components that can be present only as alternatives to each other. For example, a list of “A, B, or C” indicates options of: A; B; C; A and B; A and C; B and C; and A, B, and C. Correspondingly, the term “or” as used herein is intended to indicate exclusive alternatives only when preceded by terms of exclusivity, such as “only one of,” or “exactly one of.” For example, a list of “only one of A, B, or C” indicates options of: A, but not B and C; B, but not A and C; and C, but not A and B. In contrast, a list preceded by “one or more” (and variations thereon) and including “or” to separate listed elements indicates options of one or more of any or all of the listed elements. For example, the phrases “one or more of A, B, or C” and “at least one of A, B, or C” indicate options of: one or more A; one or more B; one or more C; one or more A and one or more B; one or more B and one or more C; one or more A and one or more C; and one or more A, one or more B, and one or more C. Similarly, a list preceded by “a plurality of” (and variations thereon) and including “or” to separate listed elements indicates options of one or more of each of multiple of the listed elements. For example, the phrases “a plurality of A, B, or C” and “two or more of A, B, or C” indicate options of: one or more A and one or more B; one or more B and one or more C; one or more A and one or more C; and one or more A, one or more B, and one or more C.

Also as used herein, unless otherwise limited or defined, the terms “about” and “approximately” refer to a range of values ±5% of the numeric value that the term precedes. As a default the terms “about” and “approximately” are inclusive to the endpoints of the relevant range, but disclosure of ranges exclusive to the endpoints is also intended.

Also as used herein, unless otherwise limited or defined, “integral” and derivatives thereof (e.g., “integrally”) describe elements that are manufacture as a single piece without fasteners, adhesive, or the like to secure separate components together. For example, an element stamped as a single-piece component from a single piece of sheet metal, without rivets, screws, or adhesive to hold separately formed pieces together is an integral (and integrally formed) element. In contrast, an element formed from multiple pieces that are separately formed initially then later connected together, is not an integral (or integrally formed) element.

Also as used herein, unless otherwise defined or limited, the term “substantially identical” indicates components or features that are manufactured to the same specifications (e.g., as may specify materials, nominal dimensions, permitted tolerances, etc.), using the same manufacturing techniques. For example, multiple parts stamped from the same material, to the same tolerances, using the same mold may be considered to be substantially identical, even though the precise dimensions of each of the parts may vary from the others.

Also as used herein, unless otherwise limited, a “fluid port” means any feature that provides a transition into or out of a particular system along a fluid particular flow path. Thus, for example, a fluid port can include simple openings in structures that are configured for fluid flow, or more complex mechanisms such as fluid couplings (e.g., a quick-connect coupling). A fluid port can include one or more features or one or more components (e.g. may be an assembly of multiple parts) that can provide the transition in or out of a particular system. For example, a fluid port can include a fitting (e.g., a quick-connect coupling) and corresponding features (e.g., an inlet aperture) on a system (e.g., a pipe or manifold) in communication with the fitting.

Also as used herein “approach temperature” or “approach temperature differential” (ATD) means a temperature difference between a service fluid (e.g., fluid in a primary fluid loop or on a receiving side of a heat exchange process) and a process fluid (e.g., fluid used to directly cool electrical equipment in a data center). For example, for LTL heat exchangers, an approach temperature means the temperature difference between a facility coolant (e.g., a fluid in a primary loop) and a temperature of a fluid in a secondary loop that flows to electrical equipment to be cooled. An approach temperature can be a temperature between a facility water supply on a first side of a heat exchanger (i.e., a first fluid side including fluid flow elements along a primary cooling circuit), and a fluid temperature at an outlet of an “equipment side” (i.e., a second fluid side including fluid flow elements along a secondary cooling circuit) of a heat exchanger. In some cases, an approach temperature can be a temperature difference between a facility water supply and a temperature at an inlet of an equipment side of a heat exchanger. In some cases, a, approach temperature can be a temperature difference between an air and a liquid that flow through a liquid-to-air (LTA) or an air-to-liquid (ATL) heat exchanger. Further, a “minimum approach temperature differential” is a minimum rated temperature difference between a fluid on a first side of a heat exchanger (e.g., a primary or facility side) and a fluid on a second side of a heat exchanger (e.g., a secondary or equipment side). Operating a heat exchanger at an ATD that is below a minimum ATD can result in ineffective heat transfer (e.g., no heat transfer, or heat transfer in a direction opposite to an intended direction of heat transfer). For example, a minimum ATD for a given heat exchanger can be 10 degrees Celsius, as can require a temperature of a fluid on a primary side to be at least 10 degree colder than a temperature of a fluid at a secondary side (e.g., at an inlet or outlet, or any portion of the secondary fluid loop between the inlet or the outlet). In this example, if a temperature of fluid in the primary fluid loop is only 5 degrees colder than a temperature of fluid in the secondary loop, an efficiency of heat transfer from the secondary loop to the primary loop can be degraded (e.g., can be stopped). In some cases, if an ATD of a LTL heat exchanger is below a threshold value (e.g., below zero, with a fluid temperature of a fluid in a primary loop being greater than a temperature of a fluid in the secondary loop), a heat transfer can occur in a direction opposite to the desired direction (e.g., a heat can be transferred from a fluid in a primary loop to a fluid in a secondary loop).

Also as used herein, “primary side” means a fluid side of a component that includes a flow path for a fluid to which heat is transferred in a heat transfer process. In the context of liquid-to-liquid heat transfer, a primary side is positioned along a primary cooling circuit. A primary side of a component (e.g., a liquid-to-liquid heat exchanger, a CDU, etc.) defines a flow path for flow of fluid along the primary cooling circuit. In some cases, a primary side can be defined at a physical side of a component. For example, a heat exchanger can include an inlet and an outlet along a primary cooling circuit on a first lateral side of the heat exchanger. In some cases, a primary side does not correspond to a physical side of a component. For example, an inlet of a heat exchanger along a primary cooling circuit can be provided on a first physical side of the heat exchanger, and an outlet of the primary cooling circuit can be provided at a second physical side of the heat exchanger, opposite the first side. Also as used herein, “secondary side” means a fluid side of a component that includes a flow path for a fluid from which heat is transferred in a heat transfer process. For example, a liquid-to-liquid heat exchanger includes a secondary side (e.g., a side fluidly along a technology cooling system) having a secondary inlet for receiving a fluid along a secondary cooling circuit, and a secondary outlet through which fluid along the secondary cooling circuit exits the heat exchanger. The liquid-to-liquid heat exchanger further includes a primary side (e.g., a side fluidly along a facility water system) having a primary inlet for receiving a fluid along a primary cooling circuit, and a primary outlet through which fluid along the primary cooling circuit exits the heat exchanger. Elements of the primary side and the secondary side can be positioned at the same physical side of the heat exchanger, and a primary side and secondary side do not necessarily correspond to physical sides of the heat exchanger.

Also as used herein, “chilling” and variations thereof (e.g., chill, chiller, etc.) mean to cool a fluid via a refrigeration cycle. Chilling a fluid thus means transferring a heat from the fluid to a refrigerant within a refrigeration cycle (e.g., via an evaporator heat exchanger). Thus, as used herein, chilling is synonymous with refrigeration.

The following discussion is presented to enable a person skilled in the art to make and use embodiments of the present disclosure. Various modifications to the illustrated embodiments will be readily apparent to those skilled in the art, and the generic principles herein can be applied to other embodiments and applications without departing from embodiments of the disclosure. Thus, embodiments of the disclosure are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the disclosure. Skilled artisans will recognize the examples provided herein have many useful alternatives and fall within the scope of embodiments of the disclosure.

In operation, electrical equipment generates a heat that, in some cases, must be transferred away from electrical equipment to prevent a degrading or a destruction of the electrical equipment. For example, modern computing loads can require large amounts of electrical computing equipment (e.g., servers, networking switches, storage devices, etc.) to support given compute loads. Computing equipment within a data center can be arranged in racks (e.g., in shelves of racks), which in turn can be arranged in rows within a data center. As compute demand increases, and technological advances provide greater computing density (e.g., an amount of CPUs or GPUs within a given volume) computing equipment generate an increasing heat load within a data center. Cooling systems can be provided within a data center to remove heat from computing equipment and other electrical equipment within the data center. In some cases, cooling systems can include an air cooling of equipment (e.g., a transfer of heat away from a component induced by an air flow across the component). In some cases, liquid cooling can be utilized to removed heat from electrical equipment (e.g., coolant can flow across a cold plate in thermal connection with a CPU, GPU, or ASIC chip to transfer heat away from the chip). Data canter can use a combination of liquid cooling and air cooling to provide cooling for electrical equipment within the data center.

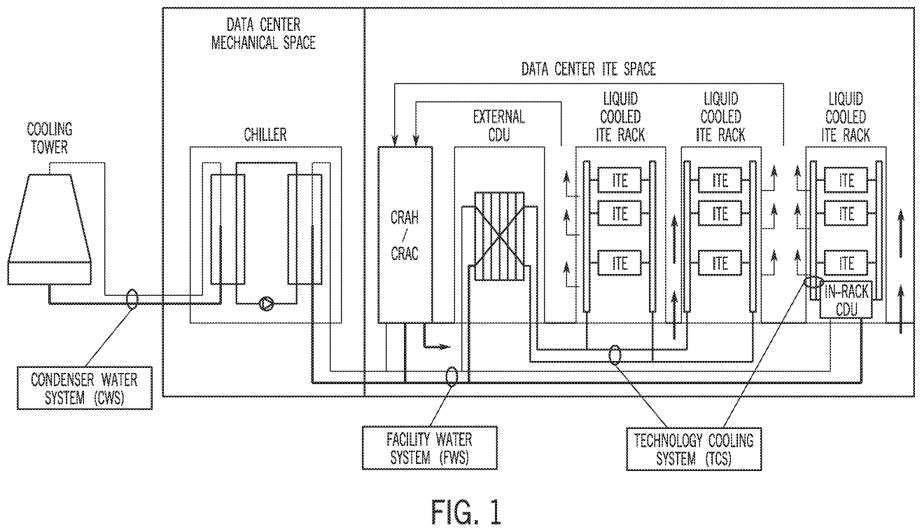

For example, FIG. 1 illustrate an example cooling arrangement for a data center. As shown, a data center can include a Data Center mechanical Space, and a Data Center Information Technology Equipment (ITE) space. The Data Center ITE space can include racks of electrical equipment, which, as illustrated, include Liquid Cooled ITE Racks. The Data Center Mechanical Space can include cooling systems for the data center, which, as illustrated, includes a Chiller. The Chiller can chill a fluid for a Facility Water Supply (FWS) and provide that chilled water for use in cooling equipment within the Liquid Cooled ITE Racks. In some cases, water or other coolant, chilled by a chiller of a data center can be chilled to a desired temperature. In some cases, a temperature of a water provided by the chilled can be determined in relation to a set point for another parameter (e.g., a flow rate, a differential temperature, a pressure, a dew point, etc.).

In the illustrated example, the FWS chilled by the Chiller is provided to CDUs which can include LTL heat exchangers to transfer heat from a fluid in a Technology Cooling System (TCS) to the FWS. As illustrated, CDUs can include an External CDU (e.g., an in-row CDU comprising a rack along a row of racks within the data center) and an In-Rack CDU (e.g., a CDU housed within a rack that can include the electrical and computing equipment to be cooled). The TCS can comprise a secondary cooling circuit, and the FWS can comprise a primary cooling circuit, with the CDUs providing a heat transfer from the fluid of the secondary cooling circuit to the fluid of the primary cooling circuit, and thus, a heat transfer away from the electrical and computing equipment within the Liquid Cooled ITE Racks.

In the illustrated example, the Data Center also includes a Computer Room Air Handling or Computer Room Air Conditioning (CRAH/CRAC) system to maintain a temperature of air within the data center. Thus, electrical equipment within the Liquid Cooled ITE Racks can further be cooled by a flow of cool air through the racks. Additionally or alternatively, air cooling units (e.g., ATL or LTA units) can be provided within a data center to provide air cooling to electrical and computing equipment within the data center.

Data center cooling systems, including as illustrated in FIG. 1 can impose inefficiencies for a system, and con further lack scalability and modularity needed for modern computing loads. Further, the cooling capacity of conventional data center cooling systems can be limited by constraints in the system, including a cooling capacity of a facility chiller. For example, a facility chiller can impose an operational cost on a system, including when chilled water is only used for a portion of equipment within a data center. Facility chillers can provide an output that is designed to accommodate a full capacity of a data center, but, in practice, is provided to a subset of the electrical equipment within the data center. In some cases, when environmental conditions permit, facility chillers are bypassed, and fluid along a FWS is cooled through other means (e.g., through exposure to a cold environment, through use of a cooling tower, etc.). Further, facility chillers can occupy a space within a data center that is not commensurate with the utilization of the facility chiller. Facility chillers can required large capital expenditures that can increase an operational cost of a data center relative to the amount of compute capacity of the data center. Additionally, facility chillers can require a mechanical space within a data center (e.g., the Data Center Mechanical Space illustrated in FIG. 1) that can require specialized power infrastructure, hydraulic infrastructure, etc. It can therefore be advantageous to provide systems and methods for cooling electrical equipment that can operate independently of a facility chiller, or can allow equipment within a data center to be cooled with minimal operation of a facility chiller (e.g., can operate to allow a bypass of the chiller for a maximal amount of operational time).

Data center systems including facility chillers can lack a modularity required by modern computing workloads. For example, racks of computing equipment within a data center can include computing equipment generating differing heat loads and having unique cooling requirements. For example, a portion of racks with a data center can include computing equipment having central processing units (CPUs), while other racks within the data center can include computing equipment having graphics processing units (GPUs), application-specific integrated circuits (ASICs), field programmable gate arrays (FGPAs) etc. As a computing power of individual chips (e.g., CPUs, GPUs, ASICs, FPGAs, etc.) increase, a maximum allowable temperature for the chip (e.g., a maximum temperature of a chip lid) can decrease to prevent overheating of the chip. In some cases, for example, a maximum temperature for a CPU chip (e.g., a maximum temperature of a chip lid of the CPU chip) can range from about 58 degrees Celsius to 85 degrees Celsius, while a maximum temperature for a GPU or ASIC chip can range from about 63 degrees Celsius to about 100 degrees Celsius. In this example, a facility chiller could not modularly provide cooling for the racks requiring cooling for CPUs and GPUs, but would either provide an overcapacity of cooling, reducing an efficiency, or provide insufficiently chilled water along a FWS as can be insufficient for a portion of the compute load (e.g., the CPU chips). In order to provide sufficient cooling capacity for the CPUs, the temperature of the fluid along the FWS is required to be below the maximum temperature for the CPU chips (e.g., 58 C to 85 C), as could be more capacity than required for racks housing chips of other varieties. Thus, a facility chiller can operate inefficiently and can increase a power consumption of a data center.

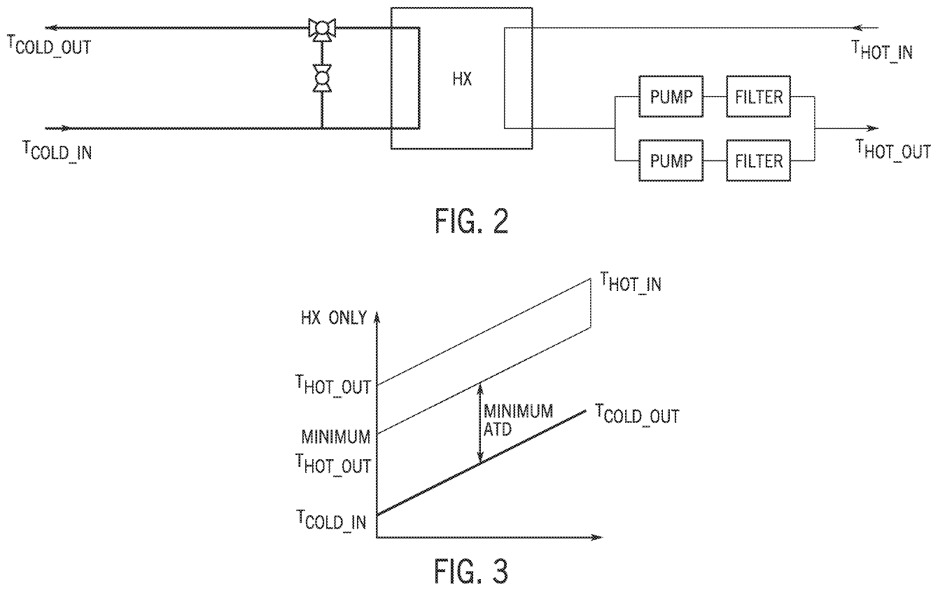

FIG. 2 illustrates an example LTL CDU (e.g., either or both of the External CDU and the In-Rack CDU shown in FIG. 1). As shown, the CDU includes a LTL heat exchanger (HX) with a primary side (e.g., along a FWS) and a secondary side (e.g., along a TCS). The primary side and secondary side, as used herein are fluid sides of HX, and may be positioned physically at any point along the HX. For example, a primary inlet can be positioned fluidly along the first side and a secondary inlet can be positioned fluidly along a secondary side, even in the primary inlet and the secondary inlet are provided in the same physical side of the HX. Fluid of the FWS (e.g., chilled fluid) can enter the CDU at an inlet at a primary inlet temperature T_{Cold_In} and can exit at an outlet at a primary outlet temperature T_{Cold_Out}. The primary side can include valving arrangements to selectively allow flow through either or both of the LTL HX and a bypass. The valves can be operated to allow flow to cither flow through the LTL HX or bypass the LTL HX to achieve a desired operating parameter (e.g., pressure, temperature differential, flow rate, heat transfer rate, etc.). Fluid of the TCS (e.g., fluid including heat for a computing load) can enter the CDU at a secondary inlet at a secondary inlet temperature T_{Hot_In} and can exit at a secondary outlet at a secondary outlet temperature T_{Hot_Out}. The primary side can include pumps for inducing a flow of fluid through the secondary cooling circuit, and filters and filtration systems to ensure a purity of the fluid in the secondary cooling circuit (e.g., the TCS). In some cases, the HX, pumps, valves, and filters can be housed within a CDU rack. In some cases, according to some aspects of the disclosure, as described further below, portions of a CDU can be housed within separate racks (e.g., pumps can be provided within a pump frame, a HX can be provided within a HX frame, etc.).

Referring now to FIGS. 2 and 3, a LTL HX, (e.g., the LTL HX shown in FIG. 2) can be rated for a minimum ATD. For example, the LTL HX can provide a heat transfer at a rated efficiency when the primary inlet temperature T_{Cold_In} is colder than the secondary inlet temperature T_{Hot_In} by at least the ATD. In some cases, the minimum ATD can be defined as the temperature difference between the fluid along other portions of the primary cooling circuit and the secondary cooling circuit. For example, as shown in FIG. 3, the minimum ATD can be defined between a portion of the fluid along the primary side between the primary inlet and the primary outlet, and a portion of the fluid along the secondary side between the secondary inlet and the secondary outlet. When a temperature of the fluid in the FWS (i.e., on the primary side of the CDU shown in FIG. 2) exceeds a temperature threshold defined as the temperature of the fluid in the TCS (i.e., on the secondary side of the CDU shown in FIG. 2) minus the ATD, the cooling efficiency of the LTL HX can be degraded (e.g., the LTL HX can cease to provide heat transfer from the fluid of the secondary side to the fluid of the primary side). Additionally, if a temperature of the fluid along the primary side exceeds a temperature of the fluid along the secondary side (e.g., T_{Cold_In}>T_{Hot_In} or T_{Cold_Out}.>T_{Hot_Out}), heat can be transferred from the fluid along the primary side to the fluid along the secondary side. Thus, while traditional LTL HX CDUs can be relatively inexpensive to operate, (e.g., due to a passive heat transfer within the LTL HX), a cooling capacity of a traditional LTL HX can be limited by a temperature of a fluid provided from a FWS. A LTL CDU that is suitable for cooling of electrical equipment having GPU chips at a certain temperature of the FWS (e.g., at a certain T_{Cold_In}) can be unsuitable for cooling of electrical equipment having CDU chips at the same temperature of the FWS. Further, in the arrangement shown in FIGS. 1 and 2, cooling systems can be susceptible to system failures and environmental conditions. For example, in the event of a failure of a facility chiller (e.g., the Chiller shown in FIG. 1) a CDU can cease to provide sufficient cooling capacity for a given rack. In some cases, including in data centers without facility chillers, a temperature of fluid along a FWS can differ with an environment, and can fluctuate with an ambient external temperature. In some cases, cooling systems designed to provide cooling for certain cooling equipment can be rendered obsolete by technological advances in chip technology that can require a greater cooling capacity than the cooling system was rated for.

Modular cooling systems according to the present disclosure can address these and other issues by providing mixed-mode cooling (e.g., combinations of passive LTL heat transfer, chiller systems, and LTA heat transfer) that can be adaptable for given computing workloads, and can provide adjustable cooling capacity according to environmental conditions and computing demands. In some cases, a modular cooling system can include one or more chillers to provide a heat transfer from a fluid of a secondary cooling circuit (e.g., a TCS) to a fluid of a primary cooling circuit (e.g., a FWS) in addition to one or more LTL HXs. A flow of fluid through the one or more chillers and the one or more LTL HXs can be controlled to provide a cooling capacity for a heat load (e.g., electrical equipment) based on the cooling requirements of the electrical equipment (e.g., a maximum temperature of a chip lid of the electrical equipment) and parameters of the fluid along the primary cooling circuit (e.g., a temperature of a fluid at a primary inlet of a CDU). In some cases, a modular CDU can be housed within a rack of a data center, and individual cooling modules can be provided in the CDU. For example, a CDU can include a plurality of chilling modules and a plurality of LTL HX modules. Modules within a CDU can be hot-swappable, and can provide different cooling capacities. For example, a CDU can include a first chiller module having a first cooling capacity and a second chiller module having a second cooling capacity that is less than the first cooling capacity. When a cooling capacity required for a heat transfer between fluid in a TCS and FWS is less than or equal to the second cooling capacity, the CDU can operate the second chiller module to provide a heat transfer. Thus, a chilling capacity can be optimized for a given load at given conditions. Optimizing a cooling capacity of a modular cooling unit can increase a power efficiency of the system, as, in some cases, chilling module providing greater cooling capacity can also require more power to operate.

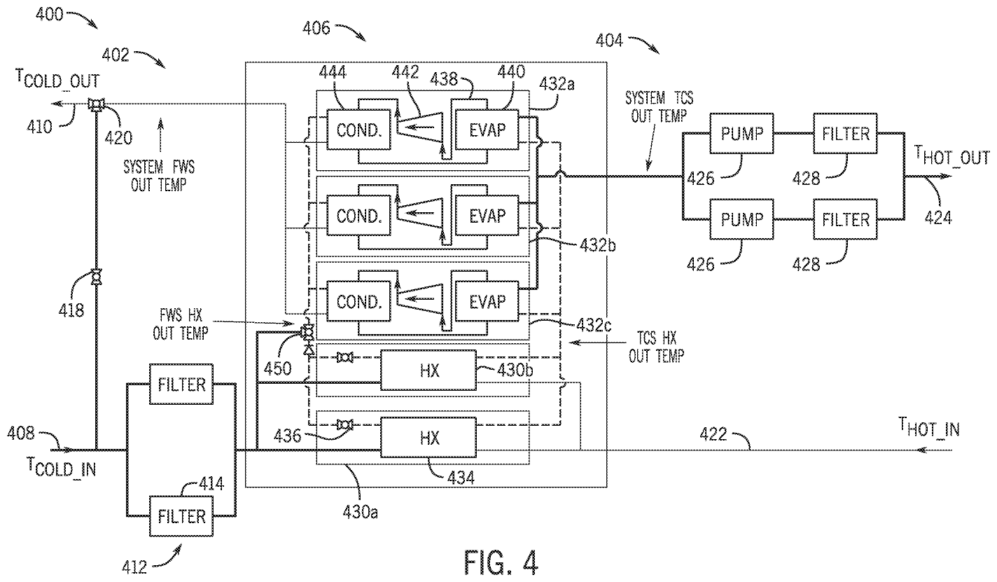

In this regard, FIG. 4 illustrates an example modular CDU 400 according to some embodiments of the present disclosure. The CDU 400 defines a primary side 402 (e.g., a side in fluid communication with a FWS) including plumbing elements and piping for a fluid along a primary cooling circuit, and a secondary side 404 (e.g., a side in fluid communication with a TCS) including plumbing elements and piping for a fluid along a secondary cooling circuit. The Modular CDU 400 can include a heat exchange portion 406 positioned between the primary side 402 and the secondary side 404, the heat exchange portion configured to provide a heat transfer from fluid within the secondary cooling circuit (e.g., the TCS) to fluid within the primary cooling circuit (e.g., the FWS). In the illustrated example, the primary side 402 includes a primary inlet 408, and a primary outlet 410. A temperature of fluid flowing into the Modular CDU 400 at the primary inlet 408 is denoted as T_{Cold_In}, and a temperature of fluid flowing out of the Modular CDU 400 at the primary outlet 410 is denoted as T_{Cold_Out}. As shown, the Modular CDU 400 can include a primary filter assembly 412 including one or more filters 414 (e.g., two filters 414 as shown). Fluid from the primary inlet 408 can flow through one or more of the filters 414 prior to flowing into elements of the het exchange portion 406 (e.g., as can advantageously shield heat exchanges and other heat exchange elements of the heat exchange portion 406 from harmful particulate matter and impurities of fluid within the primary cooling circuit). Further, the primary side 402 can include a bypass valve 418 to allow fluid along the primary cooling circuit to bypass the heat exchange portion 406 and flow directly from the primary inlet 408 to the primary outlet 410. A valve 420 (e.g., a three-way ball valve) can further be provided downstream of the heat exchange portion 406 (e.g., fluidly between the heat exchange portion 406 and the primary outlet 410), and the valve 420 can operate to selectively allow or deny fluid flow through one or both of the heat exchange portion 406 and a bypass of the heat exchange portion 406 (e.g., a flow of fluid directly between the primary inlet 408 and the primary outlet 410 through the bypass valve 418). In some cases, a Modular CDU does not include filtration elements along a primary side. In some case, a Modular CDU does not include valves for a bypass of a heat exchange portion of the Modular CDU. In some cases, a filtration assembly can be housed in a rack separate from the Modular CDU, and fluid of the FWS can flow through the filtration assembly before flowing into a primary inlet of the Modular CDU.

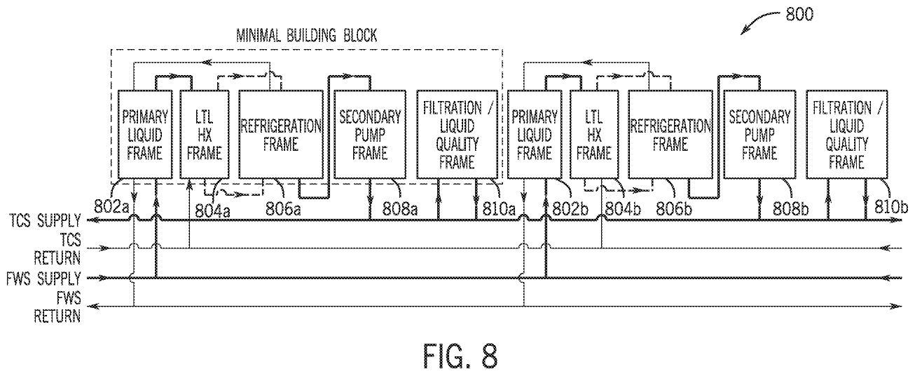

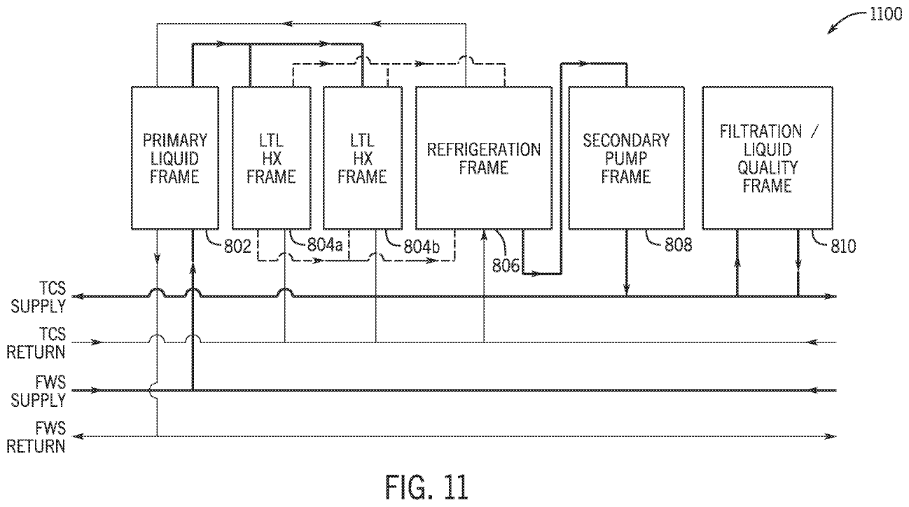

As further shown in FIG. 4, the secondary side 404 can include a secondary inlet 422 (e.g., a fluid inlet receiving a fluid heated by a heat load) and a secondary outlet 424 along a TCS. Fluid heated by a heat transfer from computing equipment (e.g., the Liquid Cooled ITE Racks shown in FIG. 1) can flow into the Modular CDU 400 at the secondary inlet 422 and flow out at the secondary outlet 424 to cool the computing equipment. A temperature of fluid flowing into the Modular CDU 400 at the secondary inlet 422 is denoted as T_{Hot_In}, and a temperature of fluid flowing out of the Modular CDU 400 at the secondary outlet 424 is denoted as T_{Hot_Out}. Fluid along the secondary cooling circuit can flow from the secondary inlet 422 through the heat exchange elements in the heat exchange portion 406 and through the secondary outlet 424. In some cases, a bypass loop can be provided between a secondary inlet and a secondary outlet of a Modular CDU to selectively allow a fluid within a secondary cooling circuit to bypass a heat exchange portion of the Modular CDU. In the illustrated example, the secondary side 404 includes pumps 426 and secondary filters 428. The pumps 426 can induce a fluid flow along the secondary cooling circuit, and the filters 428 can filter a particulate matter out of a fluid within the secondary cooling circuit, as can advantageously extend a life of downstream components (e.g., manifolds, cold plates, etc.) along the secondary cooling circuit. As shown, the pumps 426 and filters 428 can provide redundant flow paths, and can be operate in dual pump operating mode to increase a flow through the system, or a failover or primary/secondary operating mode to provide a resiliency for the system against failure of a single component (e.g., one of the pumps 426). As discussed further below with respect to FIGS. 8-12, filtration systems (e.g., filters) and pumping elements (e.g., pumps) can be housed externally to a Modular CDU. For example, pumping racks can be provided within a data center to house one or more pumps, and can be installed upstream or downstream of a Modular CDU to provide a pumping capacity necessary to achieve a cooling capacity along a secondary cooling circuit (e.g., a TCS). Similarly, filtration systems can be separately housed in a Filtration Rack, and can be provided upstream or downstream of a Modular CDU along a secondary cooling circuit. In some cases, one or more of pumps and filters of a modular CDU can be provided in a blind mate and/or hot-swappable arrangement within a rack. For example, a rack of a Modular CDU can be arranged with shelves (e.g., similar to a standard server rack), and blind mate connectors can provide electrical and fluid ports to integrate with components inserted into a given shelf. A pumping module including one or more pumps can be inserted into the Modular CDU at a shelf, and can automatically integrate with a secondary cooling circuit via blind mate connections when inserted into the shelf. In some cases, cooling modules of a modular CDU can be configured for toolless insertion into and removal from a modular CDU. Other embodiments are possible.

A heat exchange portion of a modular CDU can include one or more heat exchange modules as can be operated to provide a cooling capacity for computing and electrical equipment downstream of the modular CDU (e.g., along a secondary cooling circuit). In some cases, a modular CDU can include one or more passive LTL HX modules (e.g., modules including brazed plate heat exchangers, U tube heat exchangers, etc.), and one or more chiller modules (e.g., heat exchange modules effecting a refrigeration cycle to cool a fluid in a secondary cooling circuit). In some cases a Modular CDU can include LTA modules (e.g., modules including a LTA heat exchanger and one or more fans). A Modular CDU can be operated to provide an optimal cooling capacity for a given load, and can adapt to changing environmental conditions. For example, if a cooling capacity of a passive LTL HX module is exceeded (e.g., a temperature of fluid of the FWS is too high), one or more chiller modules can be operated to provide a desired cooling capacity and heat transfer from fluid in the TCS to fluid in the FWS. In some cases, increasing a cooling capacity can require activating LTA cooling modules. For example, a failure along a FWS can result in a loss of flow of fluid along the FWS (e.g., pumping units along a primary cooling circuit can fail), and fluid of the secondary cooling circuit (e.g., the TCS) can be routed through a LTA module within the Modular CDU to provide LTA heat transfer from the fluid of the secondary cooling circuit.

In the illustrated example of FIG. 4, the heat exchange portion 406 of the Modular CDU 400 includes a first LTL HX module 430a, a second LTL HX module 430b, a first chiller module 432a, a second chiller module 432b, and a third chiller module 432c. In other examples, a modular CDU can include any number of LTL HX module and chiller modules. For example, a Modular CDU can include one LTL HX module or more than two LTL HX modules. A modular CDU can include two chiller modules, or one chiller module, or more than three chiller modules. In the illustrated example, the modular CDU 400 comprises a single rack within a data center (e.g., rack having a standard width of about 600 mm, a rack having a width that is half of a standard width or 300 mm, or a rack having a width that is a multiple of 300 mm). In some cases, including as illustrated and described with respect to FIGS. 8-12, chiller modules and LTL HX modules can be provided in separate racks. In the illustrated example, the LTL HX modules 430a, 430b are identical, each including a LTL HX 434. In some examples, LTL HX modules of a modular CDU are not identical, and include heat exchangers having different characteristics and different cooling capacities. For example, in some cases, a LTL HX with a lower surface area can provide a diminished cooling capacity, but improved flow characteristics, and a control system of a modular CDU can route flow of a primary and secondary cooling circuit through the LTL HX when a system does not require a greater cooling capacity. In some cases, a cooling capacity can be enhanced by providing one or more LTL HX in series. In the illustrated example, each of the HX 434 allows a flow of fluid of the FWS at a first side of the HX and a flow of fluid of the TCS through a second side of the HX to transfer heat from the fluid of the TCS to the fluid of the FCS. Valving can be provided to selectively allow or deny fluid flow through either or both of the LTL HX module 430a, and the LTL HX module 430b. For example, the LTL HX modules 430a, 430b can each include an outlet valve 436 which can deny a flow of fluid through an outlet of the respective HX 434, and can thus permit or deny a flow of fluid through the respective LTL HX module 430a, 430b. In some cases, LTL HX modules can additionally or alternatively include valves at an inlet of the LTL HX module. In the illustrated example, the valve 436 are provided along the primary cooling circuit. In some examples, valves can further be provided along a secondary cooling circuit (e.g., at the secondary side 404) to selectively permit or deny flow through one or more LTL HX modules. For example, in some cases, including when a temperature of a fluid in a primary cooling circuit exceeds a temperature of fluid of a secondary cooling circuit, it can be sufficient to stop a flow of fluid of the secondary cooling circuit through a LTL HX module (e.g., with or without stopping a flow of a fluid of a primary cooling circuit through the LTL HX module) to prevent a transfer of heat from fluid of the primary cooling circuit to fluid of the secondary cooling circuit. The valves 436, and any valves provided at the secondary side of the LTL HX modules 430a, 430b can be operatively connected to a control system for the Modular CDU 400 and can operate to permit or deny flow through the respective LTL HX modules 430a, 430b (e.g., along one or both of the primary and secondary liquid cooling circuits) to achieve a desired cooling capacity (e.g., a cooling capacity generated based on a maximum temperature of downstream electrical equipment and a temperature of the fluid in the FWS).

Because LTL HX modules require relatively minimal power to operate relative to LTA module (e.g., requiring operation of one or more fans) and chiller modules (e.g., requiring operation of elements of a refrigeration cycle, which can include an expansion valve and a compressor), it can be advantageous to operate a modular CDU using only LTL HX modules if the LTL HX modules provide sufficient cooling capacity to cool downstream electrical equipment. For example, if an ATD between fluid in a FWS (e.g., along the primary cooling circuit) and a TCS (e.g., along a secondary cooling circuit) is less than a minimum ATD for the electrical equipment, a modular CDU can allow flow solely through one or more LTL HX modules (e.g., without including flow through chiller modules or LTA modules).

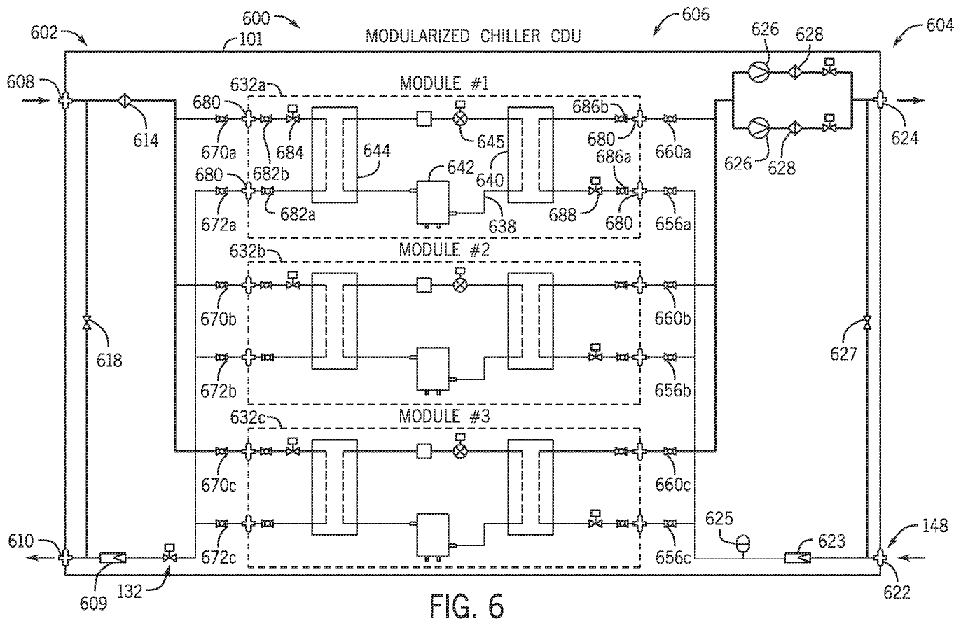

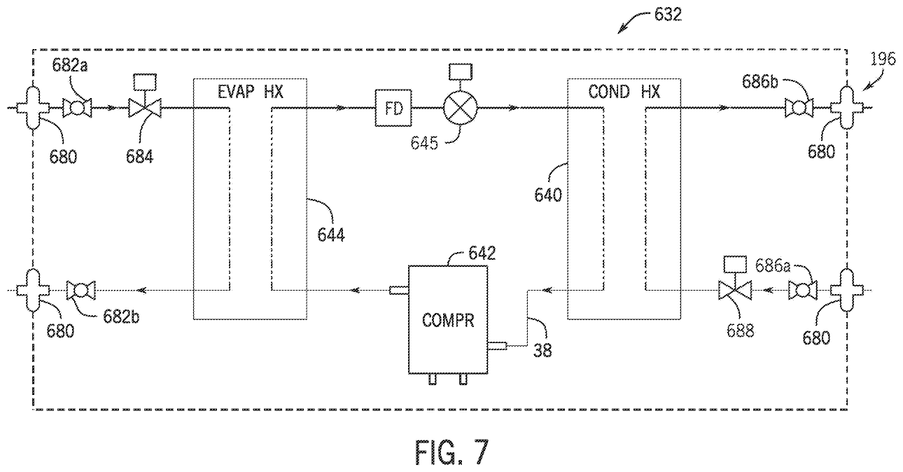

As further shown, the chiller modules 432a, 432b, 432c include a refrigeration cycle (e.g. a heat pump cycle) including a refrigerant loop 438. Within the refrigerant loop 438 a refrigerant is circulated between an evaporator 440 and a condenser 444. When fluid flows through any of the chiller modules 432a, 432b, 432c, heat is transferred from the fluid along the secondary cooling circuit to the refrigerant at the evaporator 440, and from the refrigerant to the fluid of the primary cooling circuit at the condenser 444. The chilling modules 232a, 232b, 232c include a compressor 442 fluidly between the evaporator 440 and the condenser 444, to compress a fluid before the fluid flows into the condenser. The refrigerant can enter the compressor as a gas, and exit as a liquid, and a liquid to liquid heat transfer can be performed at the condenser. The refrigerant can expand when flowing between the condenser 444 and the evaporator 440 and can change phase to a gas (e.g., immediately upstream or downstream of the evaporator 440). In some cases, the refrigerant can be any known refrigerant configured to expand and compress in a refrigeration cycle to receive a heat at an evaporator and transfer a heat to another fluid at a condenser. In some cases, an expansion valve can be provided between a condenser of a chiller module and an evaporator of a chiller module (e.g., as shown in FIG. 6). In some cases, chiller modules can include valves to allow or deny flow through the chiller module (e.g., as shown in FIG. 6). For example, a mechanized valve can be provided upstream or downstream of each of the chiller modules 432a, 432b, 432c, and the chiller modules 432a, 432b, 432c can be fluidly isolated from the primary and secondary cooling circuits when the chiller modules are not operated to increase a cooling capacity of the modular CDU 400. Chiller modules of a CDU can provide increased cooling capacity for the modular CDU as compared to LTL HX modules. For example, a chiller module (e.g., a refrigeration cycle of a chiller module) can provide heat transfer from fluid of a secondary cooling circuit (e.g., the TCS shown in FIG. 1) to fluid of a primary cooling circuit (e.g., the FWS shown in FIG. 1), even where an ATD between the fluid of the primary cooling circuit and the fluid of the secondary cooling circuit is less than a minimum ATD for a LTL HX. Further, chiller modules can transfer heat from a secondary cooling circuit to a primary cooling circuit even where a temperature of the primary cooling circuit (e.g., T_{Cold_In}) exceeds a temperature of the secondary cooling circuit (e.g., T_{Hot_In}). As described further below, chiller modules of a modular CDU can thus be activated where a change in environmental conditions (e.g., a temperature of fluid in the FWS corresponding to an ambient temperature of an environment) reduce or eliminate an effectiveness of LTL HX modules. Chiller modules of a modular CDU can further be activated when a change in a computing workload (e.g., installation of racks along a secondary cooling loop including chips with a lower maximum operating temperature) reduce a maximum temperature of a secondary cooling circuit, or a minimum ATD for LTL HX modules.

In some cases, module of a modular CDU can include elements to integrate the modules with corresponding features of the modular CDU. For example, each of the cooling modules 430a, 430b and the chiller modules 432a, 432b, 432c can be hot-swappable (e.g., can be removed and inserted into the modular CDU 400 without interrupting a cooling operation of the CDU). In some cases, each of the cooling modules 430a, 430b and the chiller modules 432a, 432b, 432c can include fluid ports (e.g., inlets and outlets along both of the primary and secondary cooling circuits), and the fluid ports can comprise blind mate connectors (e.g., quick-disconnect fittings) positioned to align with corresponding blind mate connectors (e.g., quick-disconnect fittings for corresponding ports of the modular CDU 400) of the modular CDU 400. In some cases, cooling modules can further include electrical connections that can be configured for blind mate engagement with corresponding connections of a modular CDU when the respective modules are inserted into the modular CDU.

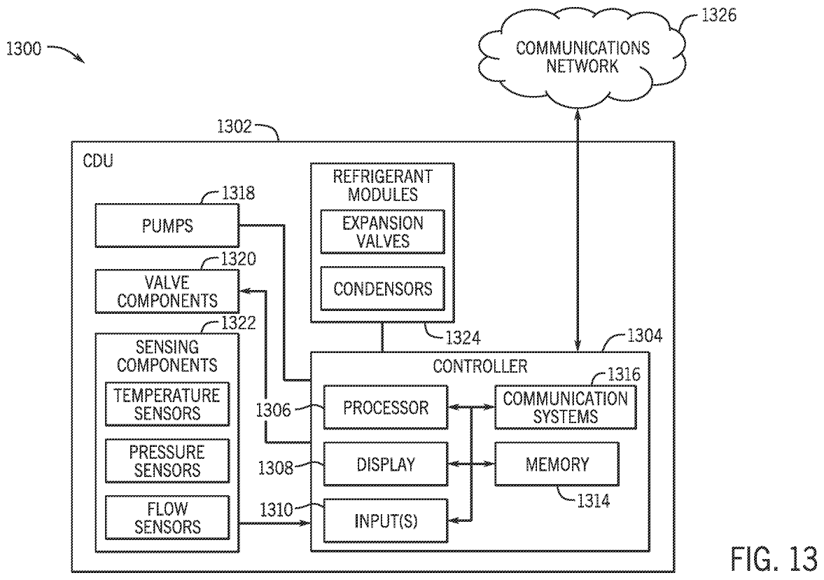

In some cases, chiller modules of a modular CDU can be identical. In some cases, chilling modules can provide different cooling capacities as can advantageously increase an efficiency of a system. For example, in some cases, a modular CDU can include a LTL HX module having a first cooling capacity, a first chiller module having a second cooling capacity, and a second chiller module having a third cooling capacity, the third cooling capacity being greater than the second cooling capacity. When a required cooling capacity is greater than a sum of the first cooling capacity, but less than a sum of the first cooling capacity and the second cooling capacity, a control system of the modular CDU can allow a flow of fluid through the LTL HX module and the first chiller module, but not through the second chiller module, as can advantageously provide a requisite cooling capacity and reduce a power inefficiency of the modular CDU. If a required cooling capacity is greater than a sum of the first cooling capacity and greater than a sum of the first and second cooling capacities, but less than a sum of the first and third cooling capacities, the control system can allow a flow of fluid (e.g., along both of a FWS and TCS) through the LTL HX module and the third chiller module. When a required cooling capacity exceeds a sum of the first and third cooling capacities, a fluid flow along both of the FWS and the TCS can be allowed through each of the LTL HX module and the first and second chiller modules. In some cases, modules (e.g., LTL HX modules, LTA modules, and chiller modules) can be arranged in parallel. For example, in the illustrated example of FIG. 4, if each of the chiller modules 232a, 232b, 232c are in operation, fluid of each of the primary and secondary cooling circuits flows through the chiller module 232c first, then through the chiller module 232b, then through the chiller module 232a. In some cases, chiller modules can be operated in parallel. As discussed further with respect to FIG. 13, chiller modules (e.g., refrigerant modules) can include local control systems to operate expansion valves, condensers, and other valves of the chiller modules. In some cases, when a chiller module is installed in a modular CDU, a control system of the modular CDU can read information of the modular CDU stored in a memory of the local control system of the chiller module. For example, a control system for a modular CDU can receive information from a chilling module that can include ATD information of the chilling module and a cooling capacity of the chilling module, and this information can be used in operating the modular CDU to optimize a cooling capacity provided by the modular CDU for a particular workload in light of operational parameters (e.g., a known temperature of a fluid of a FWS or T_{Cold_In}).

In some cases, sensors can be provided along a modular CDU, as can provide telemetry to a control system operating the CDU, and the control system can use readings from sensors of a modular CDU to optimize an operation of the CDU. In some cases, for example, temperature sensors can be provided at each of the primary inlet 408, primary outlet 410, secondary inlet 422, and secondary outlet 424 to provide temperature values for T_{Cold_In}, T_{Cold_Out}, T_{Hot_In}, and T_{Hot_Out} respectively. In some cases, temperature sensors can be provided at other point of the modular CDU including at inlets and outlets of the LTL HX modules 430a, 430b, and the chiller modules 432a, 432b, 432c. In some cases, pressure sensors can be provided to sense a pressure at any point of the modular CDU (e.g., at the inlets 408, 422, outlets 410, 424, inlets and outlets of the modules 430a, 430b, 432a, 432b, 432c, etc.). In some cases sensors can be provided to sense temperatures or pressures along the refrigerant cycles 438 of the respective chiller modules 432a, 432b, 432c. Readings from sensors (e.g., pressure sensors, temperature sensors, flow rate sensors, etc.) can be used to measure a performance of components of the modular CDU (e.g., the pumps 426, filters 238, any of modules 430a, 430b, 432a, 432b, 432c), and an operation of the modular CDU 400 can be adjusted dynamically to optimize a performance in light of readings from sensors of the modular CDU.

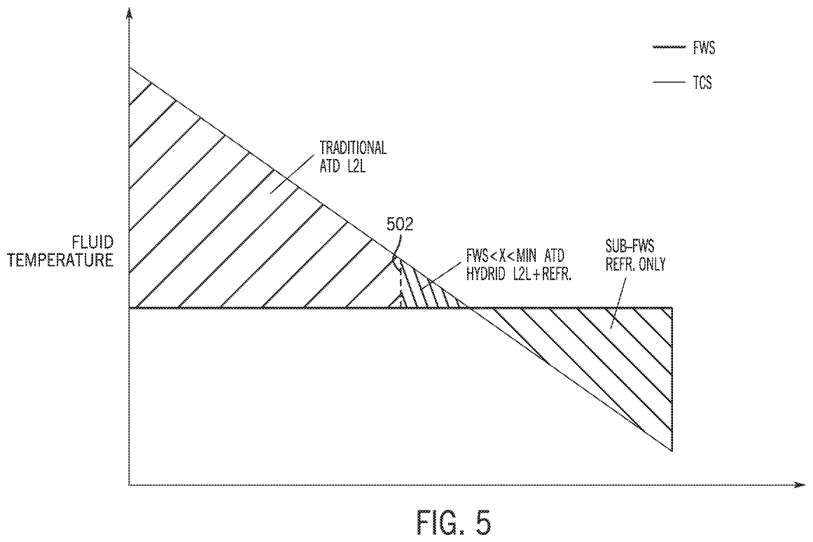

FIG. 5 is a graph illustrating operating modes of a modular CDU (e.g., the modular CDU 400) under various operating conditions, based on a relative difference between a fluid temperature of a TCS and a fluid temperature of a FWS. In the illustrated example, the dotted line 502 illustrates a minimum ATD for a system. For example, as illustrated, when a temperature of fluid along a TCS (e.g., the temperature T_{Hot_In} of the secondary inlet 422 illustrated in FIG. 4) exceeds a temperature of fluid of the FWS (e.g., the temperature T_{Cold_In} of the primary inlet 408 illustrated in FIG. 4) by an amount that is greater than the minimum ATD 502, the modular CDU can allow fluid flow through one or more LTL HX modules (e.g., modules 430a, 430b), and the LTL HX modules can provide sufficient cooling capacity for the electrical equipment downstream of the modular CDU. In some cases, a flow of fluid through a LTL HX module on either or both of a primary and secondary side can be controlled to achieve a desired heat transfer rate. For example, referring to when the approach between T_{Hot_In} and T_{Cold_In} is greater than the minimum ATD 502 required for a given electrical load (e.g., for one or a combination of ATDs sufficient to cool CDU, GPU, ASIC, FGPA chips of downstream electrical loads), a flow of fluid along the secondary loop through one or more of the LTL HX modules 430a, 430b can be increased by increasing a speed of the pumps 426 to increase a cooling capacity of the modular CDU 400. Similarly, when the approach between T_{Hot_In} and T_{Cold_In} is greater than the ATD required for the given electrical load, flow of fluid through the LTL HX modules 430a, 430b can be increased by completely closing the bypass valve 418, and allow all of the flow through the primary cooling circuit to flow through the LTL HX modules 430a, 430b.

Referring back to FIG. 5, when an ATD for a LTL HX module (e.g., LTL HX modules 430a, 430b) is lower than the minimum ATD 502, and a temperature of fluid of the FWS (e.g., T_{Cold_In}) is below a temperature of fluid of the TCS (e.g., T_{Hot_In}), it can be advantageous to operate a modular CDU in a “hybrid” mode in which one or more LTL HX modules and one or more chiller modules are operated to provide cooling capacity for the fluid of the secondary cooling circuit. For example, referring back to FIG. 4, when a control system for the modular CDU 400 determines that a different between T_{Hot_In} and T_{Cold_In} is less than a minimum ATD for the LTL HX modules 430a, 430b, one or more of the chilling modules 432a, 432b, 432c can be activated. In some cases, choosing which chilling module 432a, 432b, 432c to activate can include determining a required cooling capacity for the fluid of the secondary cooling circuit, and determining which of the chilling modules 432a, 432b, 432c or combination of chilling modules 432a, 432b, 432c provides a cooling capacity that is greater than or equal to the required cooling capacity. In some cases, a control system for the module CDU determines which chilling module 432a, 432b, 432c or combination of chilling modules 432a, 432b, 432c to activate by minimizing a cooling capacity provided by the activated chiller module or combination of chiller modules subject to the constraint that the cooling capacity is equal to or exceed the require cooling capacity. In some cases, providing the minimal cooling capacity required for cooling a downstream electrical load can optimize a power consumption of a modular CDU.

Referring back to FIG. 5, when an inlet temperature of a modular CDU along a FWS (e.g., T_{Cold_In} shown in FIG. 4) is less than an inlet temperature of the modular CDU along a TCS (e.g., T_{Hot_In} shown in FIG. 4) it can be advantageous to operate a modular CDU without providing a flow through LTL HX modules. For example, when the FWS temperature exceeds the TCS temperature, fluid of the FWS temperature would transfer heat to fluid of the TCS within a LTL HX module. Therefore, with reference to FIG. 4, when T_{Cold_In} exceeds T_{Hot_In}, the LTL HX modules 430a, 430b can be fluidly isolated from the primary and secondary cooling circuits (e.g., through closure of the valves 436 to prevent flow through the respective LTL HX modules 430a, 430b). In some cases, valves can further be provided along a secondary cooling circuit (e.g., a TCS side of the LTL HX modules 430a, 430b) to isolate the LTL HX modules from a secondary cooling circuit, as can prevent any heat transfer from fluid of the primary cooling circuit to the fluid of the secondary cooling circuit that could result from a flow of fluid of the secondary cooling circuit through the LTL HX modules. In some cases, the chilling modules 432a, 432b, 432c are isolated from the primary cooling circuit by default. For example, as shown in FIG. 4, a valve 450 can be provided to selectively allow or deny flow through the chilling modules 432a, 432b, 432c, and the valve can be external to the respective chilling modules 432a, 432b, 432c. In the illustrated example, the valve 450 is a three-way ball valve, however, other configurations are possible. In some cases, any known valves can be operated to selectively admit or deny flow through any or all of the modules 430a, 430b, 432a, 432b, 432c. In some cases, a control system for a modular CDU can continuously evaluate a temperature of a fluid along a FWS (e.g., T_{Cold_In}) and a temperature of a fluid along a TCS (e.g., T_{Hot_In}) and can selectively activate and deactivate chiller modules and LTL HX modules to achieve a cooling capacity adapted to a required cooling capacity (e.g., a cooling capacity to produce a T_{Hot_Out} that is equal to a maximum allowable temperature for cooling processing components of downstream electrical equipment such as CPUs, GPUS, ASICs, FPGAs, etc.), and can dynamically mitigate a performance degradation caused by an ATD falling below a minimum ATD for LTL HX modules of the modular CDU. Thus, embodiments of the present disclosure can allow operators of data centers to modularly adapt cooling systems of data centers to evolving computing requirements by integrating modular CDUs with existing cooling systems for cooling a fluid along a FWS. Embodiments of the present disclosure can also facilitate designs for data center cooling systems that do not require expensive and inefficient facility chillers. Further, modular CDUs can be provided along multiple secondary cooling circuits (e.g., multiple TCSs) and can provide customized cooling for computing equipment having similar cooling requirements. For example, a first modular CDU can be provided for a first secondary cooling circuit including one or more racks having CPUs to be cooled to a first maximum temperature (e.g., between about 58 C and about 85 C), and a second modular CDU can be provided for a second secondary cooling circuit including one or more racks having GPUs to be cooled to a second maximum temperature (e.g., about 63 C to about 90 C). Modular CDUs as disclosed herein can therefore increase an overall cooling efficiency for cooling electrical equipment within a data center, and can further reduce a power required to operate cooling systems of a data center.

While the previous discussion and the illustrated example of FIG. 5 show a modular CDU including chiller modules and LTL HX modules, a modular CDU can further include LTA cooling modules. For example, a LTA cooling module (not shown) can include one or more fans, and a LTA HX. The LTA HX can be positioned along a secondary cooling circuit of the modular CDU and can be selectively activated to boost a cooling capacity of a modular CDU, or replace a cooling capacity that is lost from other cooling modules within the modular CDU. For example, in some cases, a failure can occur in pumping systems of a primary cooling circuit (e.g., along a FWS) and flow of fluid through the primary cooling circuit can slow or stop. In this example, flow along the secondary circuit can be routed through an LTA module (e.g., through the selective opening and closing of valves of the modular CDU) and a heat from the fluid within the secondary cooling circuit can be cooled by flowing through a LTA HX of the LTA module, with an air flow across the LTA HX inducing the heat transfer. In some cases, a control system for a modular CDU can determine that a LTA module can provide the most efficient cooling capacity. For example, a CRAH/CRAC of a data center (e.g., the CRAC/CRAH shown in FIG. 1) can maintain an air of a cold aisle of the data center at a first air temperature, and an ATD between a temperature of a fluid inlet (e.g., a return temperature, T_{Hot_In} as shown in FIG. 5) and the first temperature (e.g., a temperature of air from a cold aisle) can exceed a minimum ATD for the LTA HX. In that case, if an ATD for the LTL HX modules of the modular CDU is below a minimum ATD for the LTL HX, the LTA module can be activated (e.g., a fluid flow along the secondary cooling circuit can be diverted through the LTA module and the fans can be powered) to provide efficient cooling for the downstream electrical load.

In the context of a modular CDU, as used herein, a “module” is an independent cooling component, including heat transfer elements for transfer of a heat from a fluid along a secondary cooling circuit (e.g., a TCS). A module can include a housing to contain the heat exchange elements, valve elements and electrical component of the module. A module can further include a “sled” or other structural components to integrate with locating features defined in a modular CDU (e.g., shelves, rails, guides, etc.). For example, a LTL HX module can include a housing with a LTL HX within the housing, a fluid inlet and fluid outlet along a primary side (e.g., along a primary cooling circuit) of the LTL HX module, and a fluid inlet and a fluid outlet along a secondary side of the LTL HX module (e.g., along a secondary cooling circuit). Valves can be provided at any or all of the fluid inlets and outlets defined for the LTL HX module and the LTL HX can include electrical connections to integrate the valves with electrical connections of a rack into which the LTL HX module is installed. In some cases, the fluid inlets and outlets and the electrical connections can comprise blind mate connections (e.g., quick disconnect fittings for the fluid inlets and outlets) as can allow an integration of the LTL HX module within the hydraulic systems (e.g., the primary and secondary cooling circuits) and electrical and communication systems of the modular CDU. In some cases, a local controller can be provided within a module and the local controller can operate to perform commands received from a control system of the modular CDU (e.g., the local controller can open and close valves of the LTL HX module in response to signals from the control system of the modular CDU). In some cases, a module, including a LTL HX module can be “hot-swappable” and can be configured for removal and insertion into the modular CDU without causing an interruption in a cooling provided by the modular CDU. In some cases, modules (e.g., LTL HX modules, chiller modules, LTA modules) can be sized to be received in standardized slots within the modular CDU. For example, in some cases, modules can define a height of 4 U or 8 U and can be inserted into a correspondingly sized shelf of the modular CDU. A modular CDU can be agnostic to a module type within the modular CDU and operators can customize a modular CDU to include desired modules. For example, an operator can decide to include two LTL HX modules and three LTA modules for a modular CDU, or any mix of heat transfer modules, according to system requirements and system parameters. In some cases, when a module is inserted into a modular CDU, a control system of the modular CDU reads operating information (e.g., a “type” or mode of heat transfer of the module, cooling capacities, ATDs, etc.) of the module, and can dynamically operate the CDU to provide an efficient cooling capacity for downstream electrical equipment given the particular modules of the modular CDU.

In some cases, a modular CDU can be provided for a given heat transfer mode (e.g., one of a LTL heat transfer, a chiller or refrigerant heat transfer, a LTA heat transfer, an ATL heat transfer, etc.). For example, FIG. 6 illustrates another example modular CDU 600, according to some examples of the disclosure. In some cases, the modular CDU 600 can be an in-row CDU, comprising a rack that can be rolled into a space along a row of electrical equipment. In some cases, the modular CDU is an in-rack CDU sized and shaped to be received into a space within a rack of electrical equipment. The modular CDU 600 can be similar to the modular CDU 400 illustrated in FIG. 4, and can include similar numbering for similar components. For example, the modular CDU 600 can define a primary side 602, a secondary side 604, and a heat exchange portion 606. In the illustrated example, the primary side 602 includes a primary inlet 608, and a primary outlet 610. The primary inlet 608 and primary outlet 610 can comprise any known fittings for a fluid flow system. For example, the primary inlet 608 and primary outlet 610 can comprise quick-disconnect fittings, or tri-clamp flange interfaces. The modular CDU 600 further includes a filter 614 immediately downstream of the primary inlet 608. In the illustrated example, the filter is a 250 micro millimeter filter, but in other examples, a filter along a primary side of a modular CDU can provide any level of filtration for fluid of the primary cooling circuit. Further, the primary side 602 can include sensors, including a flow meter 609. In some cases, as described with respect to the modular CDU 400, other sensors can be provided for a modular CDU at any point along the modular CDU including for example, temperature sensors, pressure sensors, humidity sensors, etc. The modular CDU 600 can include a bypass valve 618. The primary bypass valve 618 on the allows for a selective amount of fluid along the primary side 602 to bypass the heat exchange portion 606. In some cases, a modular CDU does not include a bypass valve along a primary side of the modular CDU.

The modular CDU 600 can further include a secondary inlet 622, a secondary outlet 624, pumps 626 and filters 628 along the secondary side 604 (e.g., similar or identical to the elements positioned along the secondary side 604 of the modular CDU 400 shown in FIG. 4). As further shown in FIG. 6, the modular CDU 600 can further include a flow meter 623 and an expansion tank 625 along the secondary side 604. In the illustrated embodiment, the expansion tank 625 is shown upstream of the heat exchange portion 606. In other embodiment an expansion tank can be positioned downstream of a heat exchange portion. In some cases, as shown, the primary side 604 include a bypass valve 627 as can allow a fluid flowing through the secondary cooling circuit (e.g., the TCS) to bypass the heat exchange portion 606 and flow directly from the secondary inlet 622 to the secondary outlet 624. In some cases a modular CDU does not include a bypass valve along a secondary side. The secondary valve 627 and the pumps 626 can be controlled by a control system of the modular CDU 600 to achieve a flow rate through the modular CDU 600 and through the heat exchange portion 606 of the modular CDU 600 to achieve a desired cooling capacity for downstream electrical components.

Further, the heat exchange portion 606 of the modular CDU 600 can include a plurality of cooling modules 632a, 632b, 632c. As shown the cooling modules 632a, 632b, 632c are chiller modules (e.g., similar or identical to the chiller modules 432a, 432b, 432c). In the illustrated embodiment, the modular CDU 600 includes three chiller modules 632. In other examples, a modular CDU includes any number of cooling modules (e.g., chiller modules, LTA modules, LTL HX modules, etc.). The following description is provided with respect to the chiller module 632a, but the description is equally applicable for the chiller modules 632b, 632c. As shown, the chiller modules 232a includes a refrigeration loop 638, including a refrigerant (e.g., any known fluid refrigerant) that is circulated through a evaporator 640 to receive a heat from a fluid along the secondary cooling circuit and through a condenser to expel heat to a fluid of the primary cooling circuit. Elements along the refrigerant loop 638 can facilitate the refrigeration cycle of the refrigerant. For example, a compressor 642 can be provided along the refrigerant loop 638 downstream of the condenser 644 and upstream of the evaporator 640. An expansion valve 645 can be provided downstream of the evaporator 640 and upstream of the condenser 644. The compressor 642 and the expansion valve 645 can be electrically controlled, and can be integrated with a control system of the modular CDU 600 when the chiller module 632a is installed in the modular CDU 600.

Valving components can be provided along a modular CDU to selectively allow fluid flow of a primary and secondary cooling circuit to flow through selected cooling modules. For example, in some cases, a modular CDU including only chiller modules (e.g., the module CDU 600) can be excluded from a flow path of a fluid in a primary and secondary cooling circuit through closure of valves of the modular CDU if a control system determines that a capacity of LTL HX CDUs (e.g., LTL HX module) is sufficient to provide a cooling to electrical equipment along a secondary cooling circuit. In some examples, flow can be allow through one or more chiller modules of a modular CDU to achieve a desired cooling capacity (e.g., the cooling capacity required to cool downstream electrical equipment to a maximum allowed temperature for the equipment). In some cases, a modular CDU can include chiller units providing different cooling capacities (e.g., a 10 KW chiller module, a 30 KW chiller module, a 50 kW chiller module, etc.) and the specific chiller modules to be activated can be selected to optimize a cooling capacity for a given heat load. As shown in FIG. 6, the modular CDU 600 can include a primary inlet valve 670a upstream of the chiller module 632a on the primary side 602, and a primary outlet valve 672a downstream of the chiller module 632a on the primary side 602. In some cases, the valves 670a, 672a can be manually operated to integrate an installed chiller module 632a within the modular CDU. For example, the valves 670a, 672a can be ball valves that can be manually shut when a chiller module is not installed in the modular CDU 600, and can be opened to allow flow when the chiller module 632a is installed. In some cases, the valves 670a, 672a can be operated by a control system of the modular CDU 600. For example, the control system can perform a decision to activate the chiller module 632a, and that activation can include powering the expansion valve 645 and the compressor 642 and opening the valves 670a, 672a to allow flow through the chiller module. Similarly, a secondary inlet valve 656a can be provided upstream of the chiller module 232a on the secondary side 604, and a secondary outlet valve can be provided downstream of the chiller module 232a on the secondary side 604. An operation of the secondary inlet valve 656a and the secondary outlet valve 66a can be similar or identical to the primary inlet valve 670a and the primary outlet valve 672a.

Further, the chiller module can include fluid connections 680 at each of a primary inlet, primary outlet, secondary inlet, and secondary outlet of the chiller module 632a. The fluid connections 680 can comprise quick disconnect fittings in some examples, and can be connected to piping within the modular CDU 600 to allow fluid to flow through the chiller module 632a along both of a primary cooling circuit and a secondary cooling circuit. In some cases, the fluid connections 680 can comprise blind mate connections that can automatically engage with corresponding connections of the modular CDU 600 when the chiller module 632a is installed within the modular CDU 600. For example, the chiller module 632 can be configured to slide into a rack of the modular CDU 600 (e.g., along shelves, guide rails, a channel, etc.), and the fluid connections 680 for each of the primary inlet, primary outlet, secondary inlet, and secondary outlet can be provided as blind mate connectors along a back surface (e.g., a back side) of the chiller module 632a. When the chiller module 632 is fully inserted, the fluid connectors 680 can be aligned with and engaged with corresponding fluid connector of the modular CDU 600. In some examples, fluid connections can comprise any known fluid connections or port systems, including, for example, fittings of a tri-clamp flange system.

A cooling module for a modular CDU can include internal valving elements that can be controlled by a control system of the modular CDU to selectively allow fluid flow through the cooling module along a primary cooling circuit and a secondary cooling circuit. For example, the chiller module 632a includes a valve 682a at a primary inlet of the chiller module 632 (e.g., immediately downstream of the fluid connection 680 at the primary inlet), and a valve 682b at a primary outlet of the chiller module 632a. The valves 682a, 682b to isolate the chiller module 632a from a primary cooling circuit, or to allow flow of fluid of the primary cooling circuit to flow through the chiller module 232a. In some cases, the valves 682a, 682b can be controlled to throttle a flow of fluid along the primary cooling circuit through the chiller module 232a to achieve a desired cooling capacity. In some cases a throttling can be performed by an additional valve 684 provided along a primary side of the chiller module 632a. In some cases, the valves 682a, 682b can be fully opened when the chiller module 232a is installed in the modular CDU 600, and the valve 684 can be controlled to allow flow of fluid of the primary cooling circuit through the chiller module 232a in response to an instruction (e.g., a signal, a message, etc.) from a control system of the modular CDU 600. Valves can similarly be provided along a secondary side of the chiller module 632a. Similarly, the illustrated chiller module 232a includes valves along a secondary side of the chiller module 232a, for example, as shown, isolation valves 686a, 686b are provided at a secondary inlet of the chiller module 232a and a secondary outlet of the chiller module 232a respectively. In some cases, the isolation valves 686a, 686b are open to allow fluid flow through the chiller module 632 by default, an can be closed to allow removal of the chiller module 232a (e.g., for servicing or replacement). The chiller module can further include a valve 688 (e.g., an actuator valve) that can be operatively connected with a control system of the modular CDU 600, and can be opened to allow flow through the secondary side of the chiller module 632a in response to a signal from the control system.

In some cases, the modular CDU 600 can be a subset of a modular CDU including additional cooling modules. For example, the schematic illustration of modular CDU 600 can be illustrate the chiller modules 432a, 432b, 432c of the modular CDU 400 shown in FIG. 4 when the LTL HX modules 430a, 430b are excluded from a flow path of the fluid along the primary and secondary cooling circuits (e.g., when the valves 436 are closed). Thus, the valving arrangements described for the chiller modules 632a, 632b, 632c can be applicable for the chilling modules 432a, 432b, 432c illustrated in FIG. 4.

In some cases, a modular cooling system can comprise modular frames including all or a portion of a CDU system. For example, the modular CDUs 400, 600 described above include cooling modules, pumps, filtration system, and bypass loops to bypass the heat exchange elements, and these components are housed within the same housing. In some cases, it can be advantageous to provide further modularity for a cooling system to allow customization for specific data center environments. For example, some data center environments can include less than ten server racks (e.g., liquid cooled ITE racks, as illustrated in FIG. 1) along a single secondary cooling loop, while in other data center environments, tens of server racks can be provided along a single secondary cooling circuit. Additionally, some data centers can include a facility chiller (e.g., the Chiller shown in FIG. 1) while other data center environments do not include a central chiller. In some data center environments, there is no facility water systems (e.g., the FWS of FIG. 1) and liquid cooling if performed using LTA cooling systems. It can therefore be advantageous to provide special purpose racks (e.g., “building blocks”) of a cooling system that can be controlled to provide a desired cooling capacity (e.g., to provide cooling for electrical equipment at a maximum allowed temperature for the electrical equipment provided ATD constraints and environmental conditions) for specific data center environments.

In this regard, FIGS. 8-12 illustrate example modular cooling systems comprising a plurality of special-purpose frames (e.g., racks) to provide cooling capacity for downstream electrical loads. In some cases, the components of the special purpose frames can be operated as described with respect to the modular CDUs 400, 600 illustrated in FIGS. 4 and 6 respectively.

For example, FIG. 8 illustrates a first example cooling system 800 to cool liquid cooled electrical equipment within a data center (e.g., the Liquid Cooled ITE Racks illustrated in FIG. 1). As shown, a FWS supply can be provided (e.g., a fluid of a primary cooling circuit) and a FWS Return can further be provided. The fluid along the FWS Supply can be a chilled fluid that is provided to cooling systems at inlets of the cooling systems, and the FWS Return can include a fluid heated by a transfer of heat from fluid of a secondary cooling circuit (i.e., the TCS). The fluid of the FWS Supply can be cool relative to the fluid of the FWS Return, and the FWS Supply is represented with a bolded line in the illustrated example to indicate this cooler temperature. Additionally, the cooling system illustrated in FIG. 8 can include a TCS Supply including cooled liquid of a TCS (e.g., a secondary cooling circuit) and a TCS Return including liquid heated by a heat transfer from electrical equipment downstream of the cooling system.

As shown, in FIG. 8, the cooling system 800 includes a first and second primary liquid frame 802a, 802b, a first and second LTL HX frame 804a, 804b, a first and second refrigeration frame 806a, 806b (e.g., in-row chiller or heat pumps), a first and second secondary pump frame 808a, 808b, and a first and second filtration frame 810a, 810b. In some cases, the frames 802a, 804a, 806a, 808a, 810a can include a minimal building block for the cooling system 800 and can provide the elements needed to provide cooling to downstream electrical equipment along the TCS Supply. In some cases, providing redundancy for frames can allow a system to continue cooling when any given frame of the cooling system experiences a failure. In some cases, redundant frames can provide “burst” capacity for operation of the cooling system for a given operation. In some cases, additional minimal building blocks (e.g., a repetition of frames 802, 804, 806, 808, 810) can increase a scalability of a cooling system.

In the illustrated example, the first primary liquid frame 802a can be a frame (e.g., an in-row cabinet or rack of the data center) providing processing, telemetry, and pressure characteristics for fluid of a FWS (e.g., a primary cooling circuit). For example, the primary liquid frame 802a can include filters to enforce a quality of liquid coolant of the FWS. Further, the primary liquid frame 802a can include valves to control a pressure and flow of fluid of the FWS through the cooling system 800. For example, the primary liquid frame can include a bypass valve to allow fluid to bypass downstream cooling frames (e.g., the first LTL HX frame 804a and the refrigerant frame 806a), and a flow of fluid through the bypass can be used to achieve a cooling capacity for the cooling system 800. The primary liquid frame can further include pumps to provide an additional pressure to induce a flow of fluid through the primary cooling loop along the cooling system 800. Further, the Primary liquid frame can include sensors (e.g., flow rate sensors, temperature sensors, pressure sensors, etc.) to provide measurements of the fluid within the primary cooling circuit as can be used by a control system to control an operation of the frames of the cooling system 800. As shown, a cool fluid of the FWS supply can flow into the primary liquid frame 802a, and the primary liquid frame 802a can provide the fluid to one or both of the LTL HX frame 804a and the refrigeration frame 806a. The fluid can return to the primary liquid frame 802a from one or both of the LTL HX frame 804a and the refrigeration frame 806a at an increased temperature, and can flow out of the primary liquid frame to the FWS Return.

The LTL HX frame 804a illustrated can be a rack including at least one LTL HX. In some cases, the LTL HX frame 804a can be similar to the modular CDU 400 shown in FIG. 4, and can include a plurality of LTL HX modules that can selectively be activated (e.g., a flow along a secondary cooling circuit can be selectively routed through all or a subset of the LTL HX modules) to provide a desired cooling capacity for the cooling system 800. In some cases, the LTL HX frame 804a includes a single LTL HX, and can further include valves to control a flow through the HX to achieve a desired cooling rate. As shown, fluid of the TCS Supply can flow into the LTL HX frame 804a. The fluid can be heated by a heat exchange from electrical equipment being cooled along the TCS (e.g., the secondary cooling circuit). In some cases, including, for example, where a temperature of fluid along the FWS supply exceeds a temperature of fluid along the TCS, the LTL HX frame 804a can isolate a HX or LTL HX modules of the LTL HX frame 804a from a flow path of the secondary cooling circuit, and fluid can bypass the LTL HX within the LTL HX frame 804a. Fluid along the secondary cooling circuit can flow out of the LTL HX frame 804a to the refrigeration frame 806a (e.g., as shown by the broken lines of FIG. 8). In some cases, a cooled fluid from a LTL HX frame can flow directly from the LTL HX frame to a TCS supply to provide cooling for downstream electrical equipment. In some cases, the LTL HX frame 804a can include a bypass that allows all or a portion of fluid flow along the secondary cooling circuit to bypass the heat exchange elements (e.g., LTL HX modules and an LTL HX) and flow directly to one of the downstream refrigeration frame 806a and the TCS Supply. Further, in some cases, a fluid of the primary cooling circuit can flow out of the LTL HX frame 804a to the refrigeration frame 808a.

The refrigeration frame 806 illustrated can include a refrigeration cycle (e.g., a condenser HX, an evaporator HX, an expansion valve, a compressor, etc.) that can effect a heat transfer from a fluid in a secondary cooling circuit to a fluid in the primary cooling circuit (e.g., as discussed with respect to chiller modules 432a of FIG. 4, and chiller modules 632a of FIG. 6). In some cases, the refrigeration frame 806a can include a plurality of chiller modules (e.g., similar to the modular CDU 600 shown in FIG. 6). A control system for the cooling system 800 can selectively activate the refrigeration frame (e.g., one or more refrigeration cycles of the refrigeration frame) to provide supplemental cooling a secondary cooling circuit (e.g., the refrigeration frame 806a can operate with the LTL HX frame 804a to provide cooling when an ATD of the LTL HX frame 804a falls below a minimum ATD). In some case, the refrigeration frame 806a can provide the entire cooling capacity of the cooling system (e.g., when a temperature of the FWS supply exceeds a temperature of the TCS). Fluid of the primary cooling circuit can flow to the refrigeration frame 806a from one or both of the LTL HX frame 804a and the primary liquid frame 802a and can return from the refrigeration frame 806a to the primary liquid frame 802a.

Fluid from one or both of the refrigeration frame 806a and the LTL HX frame 804a can proceed to the secondary pump frame 808a. The secondary pump frame can include one or more pumps (e.g., similar to pumps 426 shown in FIG. 4) to induce a pressure and flow of fluid through the secondary cooling circuit. The pumps can be controlled by a control system of the cooling system 800 to provide a flow rate that achieves a desired cooling rate for downstream electrical equipment. Fluid from the secondary pump frame 808a can proceed to the TCS Supply, and can be provided to downstream electrical equipment to provide cooling for the electrical equipment.

The filtration frame 810a can include filters for removing particulate matter and controlling a purity of the fluid along the secondary cooling circuit. In the illustrated example, fluid of the TCS supply flows into the filtration frame 810a, and fluid flow from the filtration frame 810a back into the TCS Supply. Thus, in the illustrated example, the filtration frame 810a can continuously operate to purify the liquid along the secondary cooling circuit, independently from the other frames in the system 800. In some cases, the filtration frame 810a can be provided along the TCS Return. In some cases, the filtration frame 810a can be provided in series with one or more of the LTL HX frame 804a, the refrigeration frame 806a, and the secondary pump frame 808a.

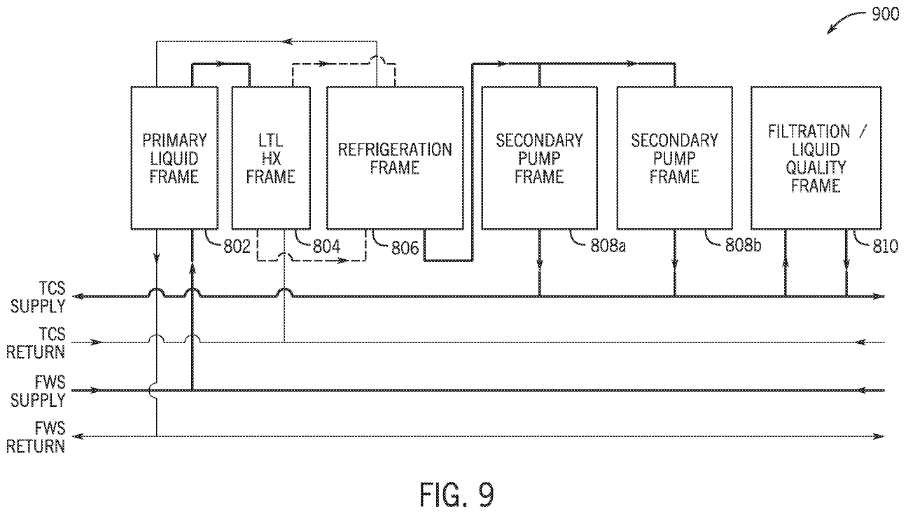

In some cases, a particular application or data center environment can require enhanced capacity for one or more elements of a cooling system. For example, where a cooling system is providing cooling to less than 10 racks of liquid cooled electrical equipment, it can be sufficient to provide a single pump frame (e.g., secondary pump frame 808a shown in FIG. 8) to provide a fluid pressure along the secondary cooling circuit. When a number of racks increases for a given secondary cooling circuit, it can be necessary to boost a pumping capacity of the cooling system. FIG. 9 illustrates another cooling system comprising special purpose frames to provide liquid cooling for components in a data center. For example, the cooling system includes a primary liquid frame 802, a LTL HX frame 804, a refrigeration frame 806, a first secondary pump frame 808a, a second secondary pump frame 808b, and a filtration frame 810. The frames of the cooling system 900 can be similar or identical to the similarly number frames of the cooling system 800 shown in FIG. 8, and the description of the frames of FIG. 8 is applicable to the frames illustrated in FIG. 9. As shown, the frames 802, 804, 806, 808a, and 810 are similarly arranged along a primary cooling circuit (e.g., the FWS) and a secondary cooling circuit (e.g., the TCS) as the frames described in FIG. 8. The cooling system 900 can include the additional second secondary pump frame 808b as can increase a capacity of the cooling system 900 to boost a pressure along the secondary cooling circuit. In some cases, the second secondary pump frame 808b can be operated in active/active mode with the first secondary pump frame 808a to increase a fluid flow rate through the secondary cooling circuit. In some case, the second secondary pump frame 808b can provide burst capacity and pumps of the secondary pump frame 808a can be activated as required to make up for a drop in pressure in the secondary cooling circuit.

In some cases, additional capacity can be provided for cooling systems for cooling of a liquid along the secondary cooling circuit. For example, the cooling system 1000 is similar to the minimal building block shown in FIG. 8, but includes a second refrigeration frame 806b along the cooling system 1000. The refrigeration frames 806a, 806b can be operated simultaneously to boost a cooling capacity of the cooling system 1000. Additionally or alternatively, the refrigeration frames 806a, 806b can provide different cooling capacities and a control system of the cooling system 1000 can selectively activate the refrigeration frame 806a (e.g., chiller modules of the refrigeration frame 806a) or the refrigeration frame 806b to achieve an optimal cooling (e.g., a cooling to a maximum allowable temperature for fluid along the secondary cooling circuit) while maintaining a cooling and power efficiency for the system 1000. In some cases, more than two refrigeration frames can be provided for a cooling system as can be advantageously adapted for a given configuration of electrical equipment of a data center. Further, in some cases, a cooling system can include any number of LTL HX frames (e.g., including no LTI HX frames), primary liquid frames, secondary pumping frames, and filtration frames.

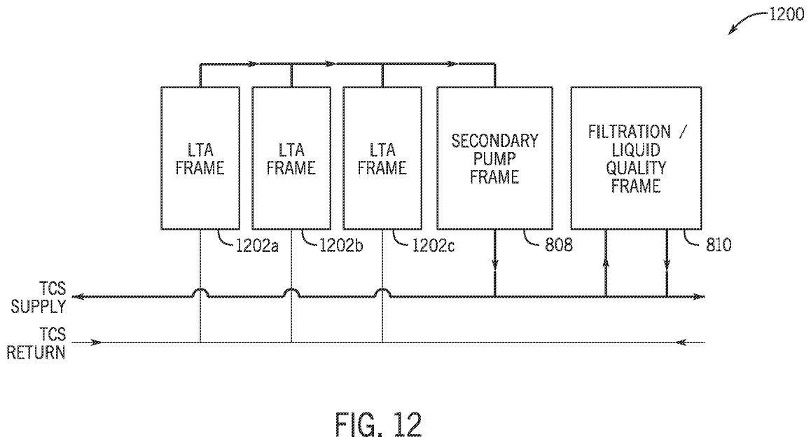

In some cases, modular cooling systems can be provided for liquid cooled electrical equipment (e.g., Liquid Cooled ITE Racks shown in FIG. 1) in data centers that do not include a facility water supply (e.g., the FWS shown in FIG. 1, the FWS Supply and Return shown in FIGS. 8-11, etc.). FIG. 12 illustrates an example modular cooling system 1200 that includes LTA cooling elements to cool electrical equipment along a cooling circuit (e.g., the TCS) without a primary cooling circuit (e.g., the FWS). As shown the modular cooling system 1200 includes a first LTA frame 1202a, a second LTA frame 1202b, a third LTA frame 1202c, a secondary pump frame 808 and a filtration frame 810. The LTA frame 1202a, 1202b, 1202c can include LTA HX or LTA HX modules (e.g., as described above) and can operate to cool a fluid of the TCS with an air flow generated across one or more LTA HX. In some cases, the LTA frames 1202a, 1202b, 1202b can be operated in parallel (e.g., simultaneously) to provide cooling for the modular cooling system 1200. In some cases, a control system for the modular cooling system 1200 can selectively activate a subset of the LTA frames 1202a, 1202b, 1202c to achieve a desired temperature for fluid of the TCS without wasting an energy operating fans to provide excess cooling capacity. In some cases, LTA frames can be provided in systems including LTL HX frames or refrigerant frames, and can provide additional cooling capacity, or backup capacity in the event of a failure of the primary cooling circuit.

Control systems can be provided for modular CDUs (e.g., the modular CDUs 400, 600 shown in FIGS. 4 and 6 respectively) and modular cooling systems (e.g., modular cooling systems 800, 900, 1000, 1100, and 1200 shown in FIGS. 8, 9, 10, 11, and 12 respectively). In this regard, FIG. 13 illustrates an example control system 1300 for a modular CDU 1302, according to some examples. The control system 1300 can include a controller 1304 for implementing a control to achieve set parameters for a system one or more pumps 1318, valve components 1320 (e.g., bypass valves, valves to selectively allow or deny fluid through cooling modules of the modular CDU 1302, etc.), sensing components (e.g., temperature sensors, flow sensors, pressure sensors, pump speed sensors, etc.) and one or more cooling modules 1324 (e.g., refrigerant or chiller modules as shown, LTL HX modules, LTA modules, etc.). The controller 1300 can control mechanical components 1318, 1320 of the modular CDU (e.g., valves, pumps, compressors, expansion valves, etc.) to selectively control flow of fluid through one or cooling modules 1324 of the modular CDU (e.g., chiller modules, LTL HX modules, LTA modules, etc.). For example, a controller can control a position of a primary bypass valve to control a rate of fluid of the primary loop through a modular CDU. A controller can control shutoff valves of the modular CDU to selectively allow or deny flow through a respective cooling module along one or more of a primary and secondary cooling circuit. A controller can control operation of an expansion valve and compressor within a chiller module (e.g., the Expansion Valves and the Condenser of the Refrigerant Module 1324 illustrated) to control a heat transfer rate of a given refrigerant loop within a modular CDU. Further, a controller can control pump speed along the secondary cooling circuit to increase flow of fluid in the secondary cooling circuit through the modular CDU and can further control the primary bypass valve as can be useful to achieve a desired heat transfer rate.

Referring still to FIG. 13, the controller 1300 may include a processor 1306, a display 1308, one or more inputs 1310 (e.g., one input, two inputs, etc.), one or more communication systems 1316 (e.g., one communication system, two communication systems, etc.), and a memory 1314. In some embodiments, the processor 1306 is a programmable logical controller (PLC). In other embodiments, the processor 1306 can be a combination of the following: a central processing unit (CPU), a graphics processing unit (GPU), and/or other hardware processors. In some embodiments, the display 1308 may include any display device, such as a computer monitor, a television, a touch screen, or the like. The one or more inputs 1310 may be received in a variety of methods, such as a keyboard, a mouse, a touch screen, a keypad, a camera, a microphone, or the like. In some embodiments, the one or more inputs 1310 are received through the display 1308 which may present the operator with various user interfaces, e.g., a display device that is touch screen. The various user interfaces may allow the operator to view the system parameters or set control parameters, such as define and/or view set points for operating parameters (e.g., ATDs, a temperature along a primary or secondary cooling circuit, etc.).

In some embodiments, the one or more communications systems 1316 can include any suitable hardware, firmware, and/or software for communicating information over communication network 1326 and/or any other suitable communication networks. For example, communications systems 1316 can include one or more transceivers, one or more communication chips and/or chip sets, etc. In a more particular example, communications systems 1316 can include hardware, firmware and/or software that can be used to establish a Wi-Fi connection, a Bluetooth connection, a cellular connection, an Ethernet connection, etc. In some embodiments, inputs can be received at the controller 1304 through the communications system 1316 over the communication network 1326. For example, an API can be provided for the modular CDU 1302 to allow an operator to control the CDU 1302 remotely. Additionally or alternatively, the controller 1304 can serve a user interface that can be accessible at a network address (e.g., through an IP address or URL), or could present a CLI which can allow for remote access to the controller 1304. Remote access to the modular CDU 1302 can be provided through other means, and the enumerated examples are provided for the purpose of illustration and not limitation.

In some embodiments, memory 1314 can include any suitable storage device or devices that can be used to store instructions, values, etc., that can be used, for example, by processor 1306 to implement control loops and algorithms of the modular CDU 1302, to store logs of the controller 1304, etc. Memory 1314 can include any suitable volatile memory, non-volatile memory, storage, or any suitable combination thereof. For example, memory 1314 can include random access memory (RAM), read-only memory (ROM), electronically-erasable programmable read-only memory (EEPROM), one or more flash drives, one or more hard disks, one or more solid state drives, one or more optical drives, etc. In some embodiments, memory 1314 can have encoded thereon a computer program for controlling operation of the controller 1304. For example, in such embodiments, processor 1306 can execute at least a portion of the computer program to receive inputs and implement control loops in response.

In some examples, a controller for a modular CDU can be remote from the modular CDU. For example, in some cases a controller can be “software-defined” and can reside on one or more servers (e.g., servers of a cloud computing platform). Further, elements of a controller (e.g., a memory, a processor, a display or interface, etc.) can be separately hosted, and can reside on separate servers or computing components (e.g., storage platforms, data-bases, containers, etc.). In some cases, a modular CDU does not have a dedicated controller, but is controlled as a component of a cooling system (e.g., modular cooling systems 800, 900, 1000, 1100, 1200). For example, a software-defined controller can provide controls for one or more racks or modules of a modular cooling system over a communications network (e.g., a dedicated management network within a DC).

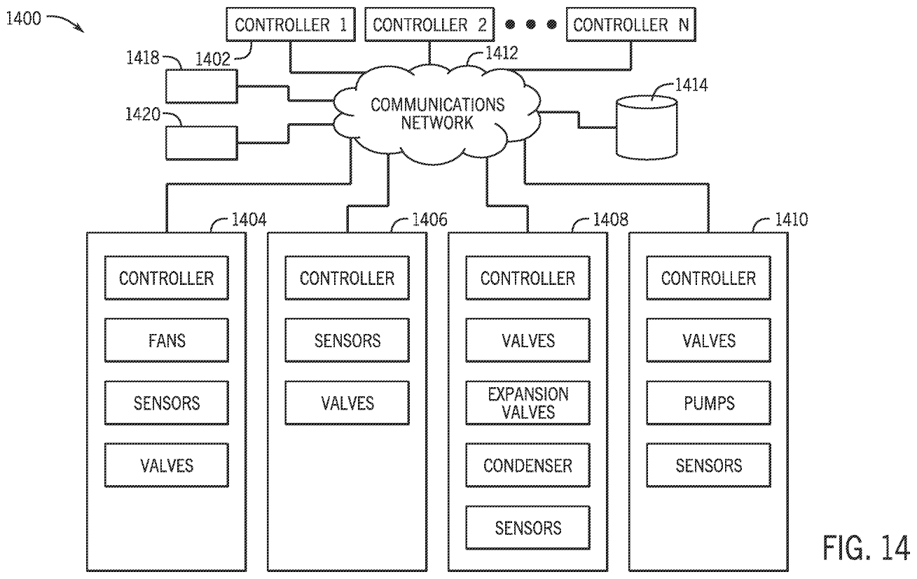

FIG. 14, illustrates an example of a control system 1400 for a cooling system of a data center. As illustrated, the system can include one or more controllers 1402 (e.g., Controller 1, Controller 2, Controller N, as shown). The one or more controllers 1402 can be software-defined and can comprise instructions stored on one or more servers within a data center. In some cases, a data center can include a plurality of cooling systems corresponding to a plurality of groupings of electrical equipment. For example, a cooling system can be provided for electrical equipment of a specific room, pod, row, aisle, or other spatial division of a data center. In some cases, a cooling system can correspond to a category of electrical equipment. For example, as discussed above, in some cases, a first rack of electrical equipment can include servers with CPU chips, and a second rack of electrical equipment can include servers with GPU chips. The first rack can require a different temperature of a fluid provided to cool the first rack than a cooling temperature of a fluid for cooling the second rack. In some cases, it can be more efficient to provide a separate cooling systems for the first rack (e.g., and racks having similar cooling requirements as the first rack) and the second rack (e.g., and racks having similar cooling requirements as the second rack). In some cases, cooling systems can be separately provided for GPU racks, CPU racks, racks of storage equipment, etc. In some cases, software-defined controllers can be provided individually for each cooling system (e.g., each modular CDU, or group of frame of a modular cooling system). In some cases, a central controller can be used to control multiple cooling systems, and individual frames or modular CDUs can be assigned to cooling systems at an interface of the controller. The control system 1400 illustrated further includes a data store 1414. The data store 1414 can be a database, a file storage system, an object storage system, a non-relational database, etc. In some cases, the data store 1414 can have state information of the control system 1400 and components thereof stored thereon 1414, as can advantageously provide resilience for the system. In some cases, an operating history of cooling system of a data center (e.g., historical data for temperatures, pressures, flow rates, modes of operation, etc.) can be stored in the data store 1414. In some cases, the data stored in a data store of a control system for cooling systems of a data center can be used to rain or refine machine learning models to improve an operating efficiency of the cooling systems.

As further shown in FIG. 14, the control system can include a communications network 1412, which can operatively connect elements of the control system. In one example, the communications network is a management network of a data center, which in some cases, can be a dedicated network that is out of band relative to the computing networks provided within the data center. In some cases, elements of the control system 1400 can connect to the communications network 1412 via an ethernet connection (e.g., a 1 Gb network connection to the dedicated management network). In other examples, the communications network can include any know wired or wireless connections, or any combination of network connections. In some cases, the communications network 1412 can include hardware, firmware and/or software that can be used to establish a Wi-Fi connection, a Bluetooth connection, a cellular connection, an Ethernet connection, etc.

In some cases, a control system can include racks of a data center including elements that can be controlled to provide a desired cooling condition within the data center (e.g., to cool a fluid of a secondary cooling circuit to a desired temperature). In some cases, any or all of the modular CDUs 400, 600 shown in FIGS. 4 and 6, and the frames 802, 804, 806, 808, 810, 1202 of the modular cooling systems shown in FIGS. 8-12 can be controlled by a control system of a cooling system as shown in FIG. 14. For example, FIG. 14 illustrates a first frame 1404, a second frame 1406, a third frame 1408, and a further frame 1410 that can be included in the control system 1400. The frames 1404, 1406, 1408, 1410 can be individual racks of cooling equipment in some examples. In some examples, frames that can be included in a control system for a cooling system can be in-rack units (e.g., similar to the in-rack CDU illustrated in FIG. 1). In the illustrated example, the first frame 1404 is an LTA frame (e.g., similar to LTA frames 1202a, 1202b, 1202c shown in FIG. 12) including a controller (e.g., similar to controller 1304 described in FIG. 13), fans, sensors, and valves. The control system 1400 can “discover” the electrical components of the frame 1404 (e.g., the controller, fans, sensors, and valves) when the first frame 1404 is installed within the data center (e.g., is integrated into the communications network 1412), and can operate the electrical components to achieve a desired temperature for a fluid in the data center (e.g., a fluid of a TCS cooled by the LTA frame 1404). As shown, the frame 1406 is a LTL HX frame (e.g., similar to frames 804a, 804b shown in FIGS. 8-11), and electrical components of the frame include a controller, sensors, and valves to control a flow of fluid through one or more LTL HXs of the frame 1406. As further shown, the third frame 1408 is a refrigeration frame (e.g., similar or identical to refrigeration frames 804 shown in FIGS. 8-11, or modular CDU 600 shown in FIG. 6). Electronic components of the refrigeration frame 1408 can include a controller, flow control valves, expansion valves along a refrigeration cycle, a compressor, and sensors. Further, the frame 1410 can be a CDU (e.g., a conventional CDU or a modular CDU), and electric components of the frame 1410 can include a controller, valves, pumps and sensors. In some cases, the frames 1404, 1406, 1408, 1410 can be provided along the same secondary cooling circuit as part of the same cooling system (e.g., modular cooling system). In some cases the frames 1404, 1406, 1408, 1410 can be provided along different cooling systems, and can further be controlled by different controllers corresponding to the different cooling systems. In some examples, a control system includes more frames, or fewer frames, or a different combination of frames than illustrated in the example control system of FIG. 14.

The electric components of the frames 1404, 1406, 1408, 1410 can integrate with the control system 1400 and can communicate with the controller 1402 to implement a process for cooling electrical equipment. For example, the controller 1402 can operate to implement a PID control for the pumps of the frame 1410, and a speed of the pumps can be controlled according to a feedback received from sensors of the frame 1410, or from sensors positioned along the cooling system. In some cases, valves (e.g., the valves of frames 1404, 1406, 1408, 1410) can be selectively opened, closed, or modulated in accordance with a signal received from the controller 1402. For example, a controller can control valves of the refrigerant frame 1408 to prevent a flow of fluid through a chiller module (e.g., similar to chiller modules 432, 632 illustrated in FIGS. 4 and 6) if an ATD of the cooling system (e.g., an ATD corresponding to a functioning LTL HX of the cooling system) exceeds a minimum ATD. The controller 1402 can open the valves of the refrigerant frame 1408 when an ATD falls below the minimum ATD to boost a cooling capacity of the cooling system, as discussed above. In some cases, a controller can implement a machine learning algorithm to optimize an operation of a cooling system based on the cooling elements (e.g., the frames 1404, 1406, 1408, 1410) included in the cooling system. In some cases, a machine learning algorithm can optimize a cooling efficiency of the cooling system based on data from the sensors of the frames 1404, 1406, 1408, 1410.

As further shown in FIG. 14, the control system 1400 can further include a facility chiller 1418 (e.g., similar to the Chiller illustrated in FIG. 1) and a CRAH/CHAC system (e.g., similar to the CRAH/CRAC shown in FIG. 1). In some cases, the control system 1400 can coordinate an operation of the chiller 1418 and the CRAH/CRAC system 1420 to further optimize an efficiency of the cooling system. For example, the control system 1400 (e.g., the controller 1402) can determine an optimal temperature for a fluid of a FWS at which to operate the cooling systems for the secondary cooling circuits within the data center, and can provide an instruction to the chiller 1418 to effect a temperature change (e.g., provide a greater or lesser chilling of the fluid of the primary cooling circuit) of the fluid of the FWS to achieve the desired temperature. Similarly, the CRAH/CRAC system 1420 can be responsive to an instruction from the controller 1402 to control an air temperature of the data center to maximize a cooling efficiency of the cooling systems within the data center.

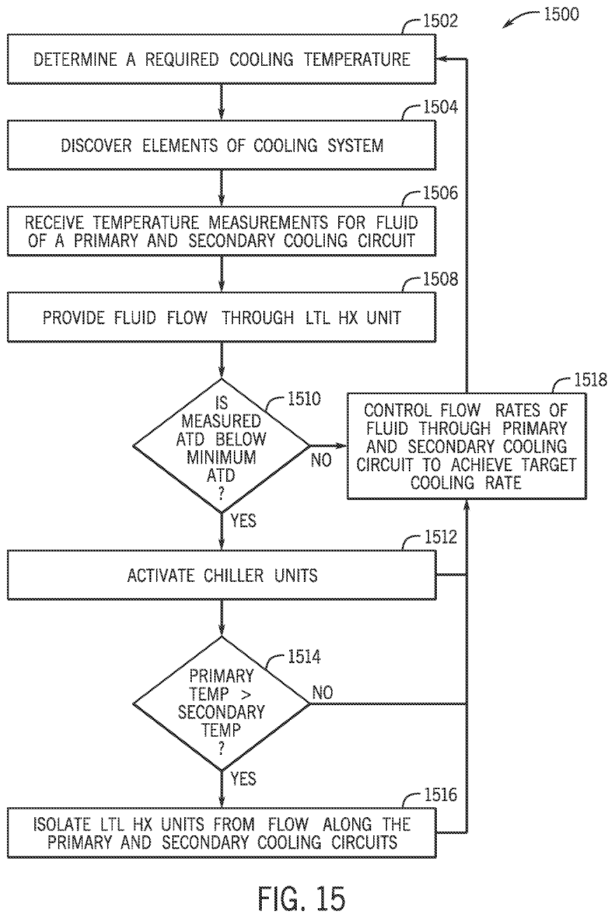

FIG. 15 illustrates an example process for operating a modular cooling system of a data center (e.g., one or more of the modular CDU 400 shown in FIG. 4, the modular CDU 600 shown in FIG. 6, the modular cooling systems 800-1200 shown in FIGS. 8-12, etc.). The process 1500 can be implemented at a controller of a cooling system (e.g., at the controller 1304 illustrated in FIG. 13, the controller 1402 illustrated in FIG. 14, etc.). At block 1502, the process can determine a required cooling temperature for a secondary cooling loop (e.g., a target temperature for a fluid along the secondary cooling circuit, a target temperature for T_{Hot_Out} shown at FIG. 4). A required cooling temperature can be a temperature to which the fluid in the secondary cooling circuit (e.g., the TCS illustrated in FIG. 1 and FIGS. 8-12) should be cooled to at an exit from the cooling system (e.g., at the secondary outlet 424 shown in FIG. 4). The required cooling temperature can be determined based on characteristics of downstream electrical equipment cooled along the secondary cooling circuit. For example, as noted above, a required cooling temperature can correspond to a maximum temperature of one or more chips to be cooled by a cooling system. As an example, if the chips to be cooled along the secondary cooling circuit comprise CPU chips, a required temperature of the fluid of the secondary cooling circuit can be a temperature sufficient to keep a temperature of a chip lid within the range of 58 C to 85 C. In some cases, a cold plate of a chip has an approach temperature, and a temperature of fluid along a secondary cooling circuit can be determined by subtracting an approach temperature for cold plates of chips from the maximum chip temperature. A volume of electrical equipment to be cooled can be used to determined a required temperature. For example, if a secondary cooling circuit includes more than 10 racks to be cooled, a required output temperature from a cooling system (e.g., T_{Hot_Out} of the modular CDU 400 shown in FIG. 4) for fluid along a secondary cooling circuit can be lower than a required output temperature for fluid along a secondary cooling circuit that includes fewer than 10 racks to be cooled. In some cases, a required temperature can be determined automatically at block 1502 based on system characteristics. For example, a control system (e.g., controller 1304 shown in FIG. 13 or controller 1402 shown in FIG. 14) can be in communication with the electrical equipment to be cooled, and can receive information (e.g., a type and number of chips to be cooled, maximum operating temperatures for the chips, etc.) about the electrical equipment from computing elements of the system. In some cases, system characteristics (e.g., information about electrical equipment along the secondary cooling circuit including a type and number of chips, a maximum operating temperature for the chips, etc.) can be programmed (e.g., by an operator) into a control system, and the control system can calculate a require outlet temperature for a fluid exiting a cooling system along a secondary cooling circuit based on the known characteristics of the electrical equipment. In some cases, a required temperature can be input directly by an operator, and determining the required temperature at block 1502 can include retrieving the known value from a memory or data store of the control system.

At block 1504, the process 1500 can discover elements of a cooling system. For example, with reference to FIG. 4, the chiller modules 432a, 432b, 432c can include local controllers including information about the chiller (e.g., cooling capacity in kW). When the chiller modules 432a, 432b, 432c are installed in the modular CDU 400, a control system can detect the connection, and the control system can read a cooling capacity of each chiller module 432a, 432b, 432c. In some cases, a control system can detect a type of frame included in a modular cooling system (e.g., the modular cooling systems 800-1200 shown in FIGS. 8-12) when the frame is installed in the modular cooling system. Information about cooling elements (e.g., the presence of modular CDUs, cooling modules of modular CDUs, frames of a modular cooling system, etc.) can allow the controller to determine an output for each of the cooling elements (e.g., a speed of pumps, an activation of chiller modules, a position of a bypass valve, a number of chiller modules to activate, etc.) to optimize a cooling efficiency or other parameter of the cooling system (e.g., the minimize a power output).

At block 1506, the process can receive temperature measurements for a temperature of a fluid along a primary cooling circuit (e.g., T_{Cold_In} shown in FIG. 4) and a temperature of fluid along a secondary cooling circuit (e.g., T_{Hot_In} shown in FIG. 4). The temperature values received at block 1506 can allow the process to determine an ATD of the LTL HXs of the system, and to evaluate if the ATD is below a minimum ATD for the LTL HXs.

At block 1508, a flow of fluid can be provided through LTL HXs of the cooling system. In some cases, fluid flow through the LTL HX can be a default mode for the cooling system. For example, with reference to FIG. 4, a maximal fluid flow can be allowed through each of LTL HX modules 430a, 430b along a primary cooling circuit on a primary side of the LTL HX modules, and fluid flow of a secondary cooling circuit can be provided along a secondary side of the LTL HX modules 430a, 430b. In some cases, LTL HX frames (e.g., LTL HX frames 804 shown in FIGS. 8-11) can receive a fluid flow along a primary and secondary cooling circuit at block 1508.

At block 1510, the process 1500 can determine if an ATD of the system (e.g., an ATD determined from the temperature measurements received at block 1506) is below a minimum ATD for the LTL HXs of the cooling system. If the ATD is above the minimum ATD, the system can proceed to block 1518 and adapt a flow of fluid in the primary and secondary cooling circuits through the LTL HXs (e.g., the LTL HX frames 804 shown in FIGS. 8-11, the LTL HX modules 430a, 430b shown in FIG. 4, etc.) to ensure that an output temperature from the cooling system for the fluid of the secondary cooling circuit is substantially the same (e.g., is identical) to the required temperature determined at block 1502.

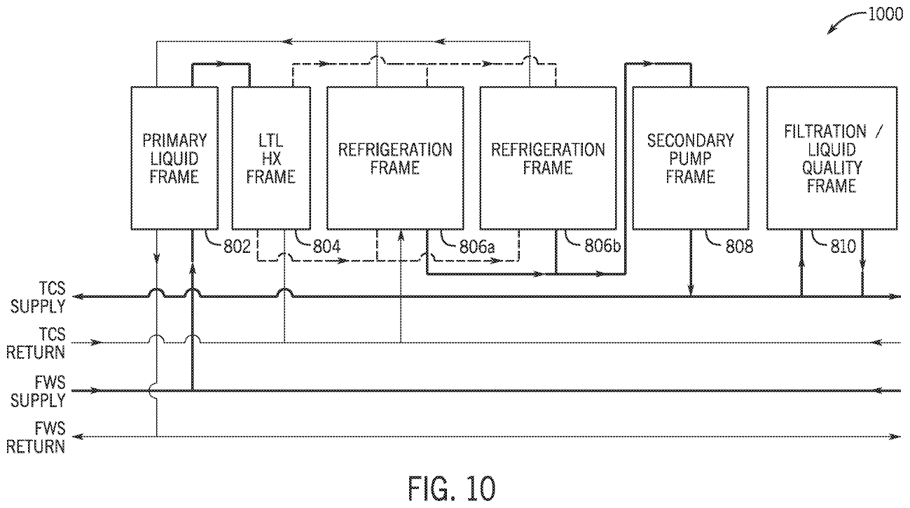

If, at block 1510, the ATD is below the minimum ATD, chilling units (e.g., chiller modules 432a, 432b, 432c shown in FIG. 4, chiller modules 632a, 632b, 632c shown in FIG. 6, refrigerant frames 806 shown in FIGS. 8-11, etc.) can be activate. Activating chilling units of a cooling system can include allowing a flow of fluid of primary and secondary cooling circuits through the chilling units, and operating valves, compressors, and expansion valves of the chilling units to provide a desired chilling capacity. In some cases, activating chilling units at block 1512 can include selecting which chilling units to activate. For example, referring to FIG. 4, in an example, chiller module 432a can provide 10 KW of cooling capacity, chiller module 432b can provide 20 KW of cooling capacity, and chiller module 432c can provide 30 kW of cooling capacity. If a level of cooling needed to achieve a required temperature (e.g., the temperature determined at block 1502) is 17 KW, the control system implementing process 1500 can choose to activate the chiller module 432b, as chiller module 432b can provide the most efficient cooling needed to achieve the required temperature. In some cases, referring to FIG. 10, at block 1510, the process can include selecting one of a plurality of refrigeration frames 806a, 806b to activate to achieve the required temperature. Once chilling units of the cooling system are activated, the process 1500 can proceed to block 1518 and can implement controls for flow through the cooling elements (e.g., the LTI HX units and the chilling units) according to control processes or algorithms (e.g., machine learning modules, PID controllers, etc.) to achieve the heat transfer rates required to cool the output fluid of the secondary cooling circuit to the required temperature. In some cases, activating chiller units at block 1512 can include selecting chilling units (e.g., chiller modules 432, 632 shown in FIGS. 4, or refrigeration frames 806 shown in FIGS. 8-11) to provide a minimal cooling capacity needed to cool the fluid of the primary cooling circuit, as can provide a cooling efficiency and minimize a waste of power within the system.

At block 1514, the process 1500 can determine if a temperature of fluid along a primary cooling circuit (e.g., the temperature of fluid of the primary cooling circuit received at block 1506, T_{Cold_In} as shown in FIG. 4, etc.) is greater than a temperature of fluid along the secondary cooling circuit (e.g., the temperature of fluid of the secondary cooling circuit received at block 1506, T_{Hot_In} shown in FIG. 4, etc.). In some cases, the determination at block 1514 is equivalent to a determination of whether an ATD of the cooling system is at or below zero (e.g., as shown in the right-most portion of the graph illustrated in FIG. 5). If the temperature of the fluid along the primary cooling circuit is not greater than a temperature of fluid along the secondary cooling circuit, the process can proceed to block 1518.

If, at block 1514, the process 1500 determines that a temperature of fluid along the primary cooling circuit is greater than the temperature of fluid along the secondary cooling circuit, the control system implementing the process 1500 can stop a flow of fluid through the LTL HXs (e.g., the LTL HX frames 804 shown in FIGS. 8-11, the LTL HX modules 430a, 430b shown in FIG. 4, etc.) along the primary and secondary cooling circuits. The process 1500 can be continuously run for a cooling system within a data center, and can dynamically update a mix of cooling (e.g., a mix of cooling from LTL HX units, chilling units, etc.) required to produce a required output temperature for a fluid of the secondary cooling circuit based on changes in system characteristics (e.g., environmental conditions, failures of components, addition or removal of cooling elements of a cooling system, addition or removal of liquid cooled ITE racks along a secondary control circuit, an inlet temperature of a fluid of a primary cooling circuit, etc.). The description of process 1500 is not intended to limit the process to the order in which the blocks of the process 1500 were described, and the block of process 1500 can be performed in a different sequence than illustrated in FIG. 15.

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the present disclosure. Thus, the present disclosure is not intended to be limited to the embodiments shown herein but is to be accorded the widest scope consistent with the principles and novel features disclosed herein.

1. A modular liquid cooling system for a data center, the modular liquid cooling system comprising:
a primary inlet and a primary outlet defining a first flow path for a first fluid;
a secondary inlet and a secondary outlet defining a second flow path for a second fluid;
a first cooling unit including a liquid-to-liquid heat exchanger having a predetermined approach temperature differential, and a first valve defining a first open position and a first closed position;
a second cooling unit including a second valve defining a second open position and a second closed position;
a controller in communication with the first valve and the second valve, the controller:
determining an approach temperature differential between the first fluid along the first flow path and the second fluid along the second flow path;
when the approach temperature differential is less than zero, providing a first signal to the first valve to move the first valve to the first closed position;
when the approach temperature differential is less than the predetermined approach temperature differential, providing a second signal to the second valve to move the second valve to the second open position.

2. The modular liquid cooling system of claim 1, wherein when the first valve is in the first open position, the liquid-to-liquid heat exchanger is positioned fluidly along the first flow path;
wherein when the first valve is in the first closed position, the liquid-to-liquid heat exchanger is not positioned fluidly along the first flow path;
wherein when the second valve is in the second open position, the second cooling unit is positioned fluidly along the second flow path; and
wherein when the second valve is in the second closed position, the second cooling unit is not positioned fluidly along the second flow path.

3. The modular liquid cooling system of claim 1, wherein the first cooling unit and the second cooling unit are housed within a first rack; and
wherein the second cooling unit includes a first chiller having a refrigerant, a compressor, an evaporator, and a condenser, the first chiller having a first cooling capacity.

4. The modular liquid cooling system of claim 3, wherein the first chiller is one of a plurality of chillers, each one of the plurality of chiller having a corresponding cooling capacity.

5. The modular liquid cooling system of claim 4, wherein the controller:
determines a cooling capacity to heat the second fluid to a target temperature; and
selects one or more chillers from the plurality of chillers to minimize a combined cooling capacity of selected chillers with the combined cooling capacity being greater than or equal to the cooling capacity.

6. The modular liquid cooling system of claim 1, wherein the first cooling unit comprises a first rack, and the second cooling unit comprises a second rack.

7. The modular liquid cooling system of claim 6, wherein the primary inlet and the primary outlet are defined in the first rack.

8. The modular liquid cooling system of claim 1, wherein the second cooling unit includes a liquid-to-air heat exchanger and a fan.

9. The modular liquid cooling system of claim 1, and further comprising a pump along the second flow path.

10. A method of cooling electrical equipment within a data center, the method comprising:
determining an approach temperature differential between a first fluid between a primary inlet and a primary outlet and a second fluid between a secondary inlet and a secondary outlet;
when the approach temperature differential is greater than zero, providing the first fluid and the second fluid to a first liquid-to-liquid heat exchanger to transfer heat from the second fluid to the first fluid;
when the approach temperature differential is less than a predetermined approach temperature differential providing the first fluid and the second fluid to a first chilling unit including a refrigerant, an evaporator, and a condenser;
transferring heat from the second fluid to the refrigerant at the evaporator; and
transferring heat from the refrigerant to the first fluid at the condenser.

11. The method of claim 10, and further comprising:
when the approach temperature differential is less than zero, stopping flow of the second fluid through the first liquid-to-liquid heat exchanger.

12. The method of claim 10, wherein the approach temperature differential is equal to a second fluid temperature at the secondary inlet minus a first fluid temperature at the primary inlet.

13. The method of claim 10, wherein the first liquid-to-liquid heat exchanger and the first chilling unit are included in a first rack.

14. The method of claim 10, and further comprising:
determining a second approach temperature differential, the second approach temperature differential being greater than the predetermined approach temperature differential; and
stopping a flow of the first fluid and the second fluid through the first chilling unit.

15. The method of claim 10, wherein the first chilling unit is one of a plurality of chilling units, each of the plurality of chilling units having a corresponding cooling capacity, the method further comprising:
determining a desired cooling capacity to cool the second fluid to a target temperature;
selecting one or more chilling units of the plurality of chilling units to provide a combined cooling capacity greater than the desired cooling capacity, the one or more chilling units being further selected to minimize a difference between the desired cooling capacity and the combined cooling capacity; and
providing a flow of the first fluid and the second fluid through each of the one or more chilling units.

16. A system to cool electrical equipment, the system comprising:
a secondary inlet and a secondary outlet, a first flow path for a first fluid being defined between the secondary inlet and the secondary outlet;
a first temperature sensor provided along the first flow path, the first temperature sensor measuring a temperature of the first fluid;
a first cooling unit including a liquid-to-liquid heat exchanger having a first cooling capacity;
a second cooling unit including a condenser, an expansion valve, an evaporator, a compressor, and a refrigerant, the second cooling unit having a second cooling capacity;
a first valve movable between a first open position in which the first fluid flows through the first cooling unit, and a first closed position in which the first fluid does not flow through the first cooling unit;
a second valve movable between a second open position in which the first fluid flows through the second cooling unit and a second closed position in which the first fluid does not flow through the second cooling unit; and
a controller in communication with the first temperature sensor, the first valve, and the second valve, the controller:
receiving a first temperature measurement from the first temperature sensor;
determining a predetermined cooling capacity to cool the first fluid to a target temperature based on the first temperature measurement;
when the predetermined cooling capacity is greater than the first cooling capacity, providing a signal to move the second valve to the second open position.

17. The system of claim 16, wherein the first cooling unit and the second cooling unit are provided in a first rack.

18. The system of claim 17, wherein the second cooling unit is configured for toolless removal from the first rack.

19. The system of claim 18, wherein the second cooling unit includes a plurality of fluid ports, wherein each of the plurality of fluid ports comprises blind mate connections to engage with corresponding fluid ports of the first rack.

20. The system of claim 16, and further comprising:
a primary inlet and a primary outlet, wherein a second flow path for a second fluid is defined between the secondary inlet and the secondary outlet;
a second temperature sensor provided along the second flow path, the second temperature sensor measuring a temperature of the second fluid;
wherein the controller:
receives a second temperature measurement from the second temperature sensor, and
when the second temperature measurement is greater than the first temperature measurement, provides a signal to move the first valve to the first closed position.
